(19) United States
(12) Patent Application Publication
(10) Pub. No.: US 2016/0070313 A1
(43) Pub. Date: Mar. 10, 2016

(54) DATA STORAGE AND TRANSFER DEVICE

(71) Applicant: Longwei Wu, Sanya (CN)

(72) Inventor: Longwei Wu, Sanya (CN)

(21) Appl. No.: 14/847,644

(22) Filed: Sep. 8, 2015

Related U.S. Application Data
(63) Continuation-in-part of application No. 62/048,267, filed on Sep. 10, 2014.
Application No. 62/048,267 is a continuation-in-part of application No. 62/147,584, filed on Apr. 15, 2015.

(30) Foreign Application Priority Data
Aug. 10, 2015 (CN) 201520596590.9

(51) Int. Cl. G06F 1/18; H01R 13/15; H01R 13/10; G11C 16/04; H01R 31/00

(52) U.S. Cl. CPC G06F 1/18; G11C 16/04; H01R 31/005; H01R 13/10; H01R 13/15

(57) ABSTRACT

A data storage/transfer device includes at least a data storage component, such as a integrated memory chip or a card reader for data storage, at least a connector on one end, e.g., a USB Type A or USB Type C connector, and at least one connector on the other end, preferably, a different type of connector, e.g., a Micro-B USB or a Lightning connector. Users may use embodiments of the present invention as a data storage device and/or data transferring cable and/or charging cable. Some embodiments may include host mode function, e.g., OTG host mode, to allow outside devices to act as hosts, e.g., a mobile phone, to read/write on data storage components of embodiments of the present invention.

### STATEMENT REGARDING FEDERALLY SPONSORED RESEARCH OR DEVELOPMENT

Not applicable

### REFERENCE TO SEQUENCE LISTING, A TABLE, OR A COMPUTER PROGRAM LISTING COMPACT DISK APPENDIX

Not applicable

### CROSS-REFERENCE TO RELATED APPLICATIONS

Provisional application No. 62/048,267, filed on Sep. 10, 2014, provisional application No. 62/147,584, filed on Apr. 15, 2015, foreign Chinese application NO. 201520596590.9, filed on Aug. 10, 2015.

### BACKGROUND OF THE INVENTION

The present invention generally relates to a data storage/transfer device, more particularly, an electronic device that stores data and/or allows data to be transferred between outside devices such as personal computers, tablets, mobile phones and others.

Because of the increasing number of personal electronic devices such as personal computers, tablets and mobile phones, the need for data transfer between these devices is getting much more prevalent. For saving data from electronic devices such as personal computers to portable data storage devices for future usage, many users carry data storage devices with them, such as flash drives. However, it is sometimes difficult to transfer data between devices that have different connector types, especially when data storage devices are designed to have only one type of connector.

Furthermore, users who have mobile devices, such as mobile phones, may need to transfer data between their mobile devices and computers in unexpected situations, e.g., when they don't have standard, long, data cables with them.

Other than the problems described above, frequently mobile devices such as mobile phones and tablets lose battery power. This necessitates carrying around a standard charger. However, in many situations, carrying a standard size charger is inconvenient. Meanwhile, the popularization of many types of charging ports, especially USB (Universal Serial Bus) charging ports, is improving not only on computers, but also on many other power sources such as wall electrical sockets and cars. Therefore, a user need a cable to connect to one of those charging ports to charge their device instead of a standard charger.

It is desirable to provide a portable solution for general data storage/transfer between devices and take advantage of numerous types of charging ports, e.g., USB charging ports.

### SUMMARY OF THE INVENTION

The present invention is a data storage/transfer device, which is comprised of at least a data storage component, at least a connector head on one end, e.g., a USB connector head, and at least one connector head on the other end, preferably, a different type of connector, e.g., a Micro USB or a Lightning connector. Users may use the present invention to store data, and/or to transfer data among a plurality of data terminals, e.g., connector heads or data storage components. The term “among a plurality of data terminals” means that the described data transfer activities occur among data terminals, that may or may not involve the data storage components of the present invention, e.g., data transfer between a computer and a mobile phone without the participation of the data storage components of the present invention. The present invention described above may also act as a charging cable for providing electric power from a power source, e.g., a USB charging port.

In some embodiments of the present invention, at least one of the connector heads has a dual or double orientation design which activates different functions when is inserted into a corresponding receptacle connector with different orientations.

In some embodiments of the present invention, at least one of the connector head has a dual or double orientation design which has the same function when is inserted into corresponding receptacle connectors with either orientations.

In some embodiments of the present invention, a mechanism or a software, may be provided to turn on or off specific mode, such as USB OTG (On-The-Go) host mode, on at least one of the outside devices connected to the present invention. When the OTG host mode is on, the present invention may become an OTG flash drive. For an example, a mobile phone which is connected to the present invention may act as a host to control the data transfer between the mobile phone and the data storage component of embodiments of the present invention. To reduce the possibility of misuse by users, connector heads that don't operate under OTG host mode may be physically blocked from usage and/or electrically cut off from data circuit.

In some embodiments of the present invention, it may include an interlock mechanism, wherein at least one connector at one end is allowed to fold backward and securely but releasably attach to other parts at different ends to reduce the total length of the present invention. To reduce the possibility of misuse by users, the embodiments may exclusively function as a data storage device, e.g., a flash drive, when connectors are attached to other parts; and these particular embodiments may exclusively function as a data transfer device, e.g., an USB cable when connectors are released to other parts;

### BRIEF DESCRIPTION OF THE DRAWINGS

FIGS. 1A-1D are simplified perspective views, respectively, of a data storage/transfer device 10 according to one embodiment of the present invention;

FIG. 1E is a simplified cross sectional view of a main body 20 according to one particular embodiment of the present invention as shown in FIG. 1A-1D;

FIG. 2 is a schematic representation of connections between contacts 12a-12h, data storage component 14 and a second connector head 34 according to one particular embodiment of the present invention as shown in FIGS. 1A-1E;

FIG. 3 is a simplified cross sectional view of a main body 320 of another embodiment of the present invention partially plugging into a standard corresponding USB type A receptacle connector 352;

FIG. 4 is a schematic representation of the connections between contacts 312a-312h, protection circuits 340a-340b, data storage component 314 and a second connector head 334 according to one particular embodiment of the present invention as shown in FIG. 3;

FIGS. 5A-5B are simplified perspective views, respectively, of a data storage/transfer device 510 according to still another embodiment of the present invention;

FIGS. 6A-6B are simplified perspective views, respectively, of a data storage/transfer device 610 according to still another embodiment of the present invention;

FIGS. 7A-7B are simplified perspective views, respectively, of a data storage/transfer device 710 according to still another embodiment of the present invention;

FIGS. 8A-8B are simplified perspective views of a data storage/transfer device 810, respectively, according to still another embodiment of the present invention without a cap 870 shown in FIG. 8E;

FIG. 8C is a simplified perspective view of data storage/transfer device 810 in a retracted position according to one particular embodiment of the present invention shown in FIGS. 8A-8B;

FIG. 8D is a simplified perspective and cross sectional view of data storage/transfer device 810 in a retracted position according to one particular embodiment of the present invention shown in FIGS. 8A-8C;

FIG. 8E is a simplified perspective view of cap 870 of data storage/transfer device 810 according to one particular embodiment of the present invention shown in FIGS. 8A-8D;

FIG. 8F is a simplified cross sectional view of data storage/transfer device 810 according to one particular embodiment of the present invention shown in FIGS. 8A-8E;

FIG. 8G is a simplified perspective view of data storage/transfer device 810 in OTG flash drive mode according to one particular embodiment of the present invention shown in FIGS. 8A-8F;

FIG. 9 is a schematic representation of the connections between contacts 812a-812h, contacts 874a-874h, an OTG ID contact 813, a data storage component 814 and a second connector head 834 according to one particular embodiment of the present invention shown in FIGS. 8A-8G;

FIGS. 10A-10B are simplified cross sectional, exploded perspective front top, front bottom views, respectively, of a main body 820 of one particular embodiment of present invention shown in FIGS. 8A-8G;

FIGS. 10C-10D are partially transparent simplified perspective front top views, respectively, of main body 820 and switch structure 880 of cap 870 according to one particular embodiment of the present invention shown in FIGS. 8A-8G;

FIG. 11 is a schematic representation of the connections of a PCB (printed circuit board) 879 of switch structure 880 shown in FIG. 10C according to one particular embodiment of the present invention shown in FIGS. 8A-8G;

FIG. 12 is a simplified exploded perspective view of switch structure 880 shown in FIG. 10C;

FIG. 13A-13E are the simplified perspective views of contact frames 1374a-1374d of a switch structure 1380 in various stages of manufacture according to still another embodiment of the present invention, respectively, in their positions with respect to each other;

FIGS. 14A-14C are simplified perspective front top, back top and back bottom views, respectively, of a partially transparent main body 1420 of a data storage/transfer device in various stage of manufacture according to still another embodiment of the present invention;

FIG. 14D is a simplified perspective view of a cap 1470 corresponding to main body 1420 of a data storage/transfer device according to one particular embodiment of the present invention shown in FIGS. 14A-14C;

FIGS. 14E-14F are partially transparent simplified perspective views, respectively, of main body 1420 and cap 1470 of a data storage/transfer device according to one particular embodiment of the present invention shown in FIGS. 14A-14C;

FIG. 15 is a partially transparent simplified perspective view of a main body 1520 of a data storage/transfer device according to still another embodiment of the present invention;

FIGS. 16A-16B are partially transparent simplified perspective views of front top, and front bottom, respectively, of a main body 1620 of a data storage/transfer device according to still another embodiment of the present invention;

FIG. 17 is a schematic representation of the connections between contacts 1512a-1512d, an USB hub controller 1518, a data storage component 1514 and a second connector head 1534 according to one particular embodiment of the present invention shown in FIG. 15;

FIG. 18 is a schematic representation of the connections between contacts 1612a-1612h, protection circuits 1640a-1640b, an USB hub controller 1618, a data storage component 1614 and a second connector head 1634 according to one particular embodiment of the present invention shown in FIGS. 16A-16B;

FIG. 19A-19C are simplified perspective views, respectively, of a cable 1940 in natural form without external force, extended state and folded state according to one embodiment of the present invention.

FIG. 20 is a simplified perspective view of a cable 2040 in natural form without external force, according to one embodiment of the present invention.

FIGS. 21A-21B are simplified perspective views, respectively, of a cable 2140 in natural form without external force and folded state, according to one embodiment of the present invention.

FIGS. 22A-22C are simplified perspective views, of a data storage/transfer device 2210 according to one embodiment of the present invention;

FIG. 23 is a simplified schematic representation of the connections between a first connector head 2215, a second connector head 2234, a receptacle connector port 2218 and a data storage component 2214, according to one particular embodiment of the present invention shown in FIGS. 22A-22C;

FIG. 24A is a simplified perspective view, of a main body 2420 and a cap 2470 of a data storage/transfer device, according to another embodiment of the present invention;

FIGS. 24B-24D are partially transparent simplified perspective views of front top, front bottom, and back top, respectively, of main body 2420 and a switch structure 2480 of cap 2470, according to one particular embodiment of the present invention shown in FIG. 24A;

FIG. 24E is a simplified cross sectional view of main body 2420 and switch structure 2480 of cap 2470, of a data storage/transfer device when in OTG flash drive mode, according to one embodiment of the present invention shown in FIG. 24A;

FIG. 24F is a simplified cross sectional view of a first connector head 2415 of one particular embodiment of the present invention shown in FIG. 24A, while plugged into a corresponding standard USB Type A receptacle connector 2452;

FIG. 25 is a simplified perspective view of a cap 2470 of one particular embodiment of the present invention shown in FIG. 24A;

FIG. 26 is a schematic representation of the connections between contacts 2412a-2412h, contacts 2474a-2474h, an OTG ID contact 2413, a data storage component 2414 and a second connector head 2434 according to one particular embodiment of the present invention shown in FIGS. 24A-24G and FIG. 25;

FIG. 27 is a simplified perspective view, of a data storage/transfer device 2710 according to one embodiment of the present invention;

FIG. 28A is a schematic representation of the connections between contacts 2774a-2774d, contacts 2712a-2712d, contacts 2782a-2782d, an OTG ID contact 2713, function switch 2754, data storage component 2714 and a second connector head 2734 according to one particular embodiment of the present invention shown in FIG. 27;

FIGS. 28B-28C are schematic representations of function switch 2754 in USB cable mode, or regular flash drive mode, respectively, according to one particular embodiment of the present invention shown in FIG. 27;

FIG. 29A is a partially transparent simplified perspective view of a main body 2720 and switch a structure 2780 of a cap 2770 according to one particular embodiment of the present invention shown in FIG. 27;

FIGS. 29B-29C are partially exploded, transparent simplified perspective views in USB cable mode, or regular flash drive mode, respectively, of main body 2720 of one particular embodiment of the present invention shown in FIG. 27;

FIG. 30 is a simplified perspective view of cap 2770 of one particular embodiment of the present invention shown in FIG. 27;

FIG. 31 is a simplified partially transparent perspective view of data storage/transfer device 2710 in OTG flash drive mode, according to one particular embodiment of the present invention shown in FIG. 27;

FIGS. 32A-32B are simplified cross sectional views, of main body 2720 and cap 2770 in regular flash drive mode, and OTG flash drive mode, respectively, according to one particular embodiment of the present invention shown in FIG. 27;

FIG. 33 is a simplified partially exploded, transparent perspective view, of a main body 3320 and a cap 3370 according to one embodiment of the present invention;

FIG. 34A is a schematic representation of the connections between contacts 3374a-3374d, contacts 3312a-3312d, contacts 3382b-3382d, contacts 3384b-3384d, an OTG ID contact 3313, a function switch 3354, a data storage component 3314 and a second connector head 3334 according to one particular embodiment of the present invention shown in FIG. 33;

FIG. 34B is a simplified schematic representation of the connections between data storage component 3314 and second connector head 3334 when a first connector head 3311 of main body 3320 is inserted into cap 3370 to activate OTG flash drive mode, according to one particular embodiment of the present invention shown in FIG. 33;

FIG. 35A is a simplified perspective view of a data storage/transfer device 3510 without a cap, according to one embodiment of the present invention;

FIG. 35B is a partially transparent simplified perspective view of data storage/transfer device 3510 according to one particular embodiment of the present invention shown in FIG. 35A;

FIG. 36 is a partially transparent simplified perspective view of a second connector 3530 attached to a main body 3520, according to one particular embodiment of the present invention shown in FIG. 35A;

FIG. 37 is a schematic representation of the connections between contacts 3574a-3574d, contacts 3512a-3512d, contacts 3582a-3582d, an OTG ID contact 3513, contacts 3557a-3557d, contacts 3558a-3558d, contacts 3559a-3559d, a data storage component 3514 and a second connector head 3534, according to one particular embodiment of the present invention shown in FIG. 35A;

FIGS. 38A-38B are a simplified perspective view, and a partially transparent simplified perspective view, respectively, of a data storage/transfer device 3810 without a cap 3870 shown in FIG. 38C, according to one embodiment of the present invention;

FIG. 38C is a simplified perspective and cross sectional view, of a main body 3820 and cap 3870, according to one particular embodiment of the present invention shown in FIGS. 38A-38B;

FIG. 39 is a schematic representation of the connections between contacts 3812a-3812d, contacts 3874a-3874d, contacts 3882a-3882d, an OTG ID contact 3813, a push switch 3854, a data storage component 3814 and a second connector head 3834, according to one particular embodiment of the present invention shown in FIGS. 38A-38C;

FIGS. 40A-40B are simplified cross sectional views of data storage/transfer device 3810 in USB cable mode and regular flash drive mode, respectively, according to one particular embodiment of the present invention shown in FIGS. 38A-38C;

FIG. 40C is a simplified cross sectional view of cap 3870 with a first connector head 3815 of main body 3820 inserted into cap 3870 to enable OTG flash drive mode, according to one particular embodiment of the present invention shown in FIGS. 38A-38C;

FIG. 41 is a simplified perspective view of a micro SD card 4114 and a main body 4120 of a data storage/transfer device according to one embodiment of the present invention;

FIG. 42 is a simplified perspective view of a data storage/transfer device 4210 according to one embodiment of the present invention;

FIG. 43 is a schematic representation of the connections between contact 4212a-4212d, a switching circuit 4218, a switching circuit 4245, a data storage component 4214 and a second connector head 4234, according to one particular embodiment of the present invention shown in FIG. 42;

FIG. 44 is a schematic representation of the connections between contact 4412a-4412d, a switching circuit 4418, a switching circuit 4445, a data storage component 4414 and a second connector head 4434, according to one embodiment of the present invention.

### DETAILED DESCRIPTION OF THE INVENTION

The present invention will be described with reference, to the following description and the accompanying figures. Generally, where elements with the same reference numbers in different figures, elements are functionally either identical or similar, unless it is contrary from the description. Each of the figures provided is to assist in understanding the nature of the present invention and is not intended as a definition of the limits of the scope of the present invention. It will be apparent, however, to one skilled in the art, that the present invention may be practiced without some or all of these specific details. In other instances, well known details have not been described in detail in order not to unnecessarily obscure the present invention.

Embodiments of the present invention have a plurality of connectors that can mate with receptacle connectors, e.g., a standard USB receptacle connector, a standard Micro USB receptacle connector, or Lightning receptacle connector. Accordingly, embodiments include means for data storage that can store and/or bidirectional transfer data between outside devices and the present invention via at least one of the connectors of the embodiments. Furthermore, at least two of the connectors of the embodiments can bidirectional transfer data with each other. In another words, when a plurality of outside devices have specified connectors described above plugged in, they may communicate with each other via the present invention.

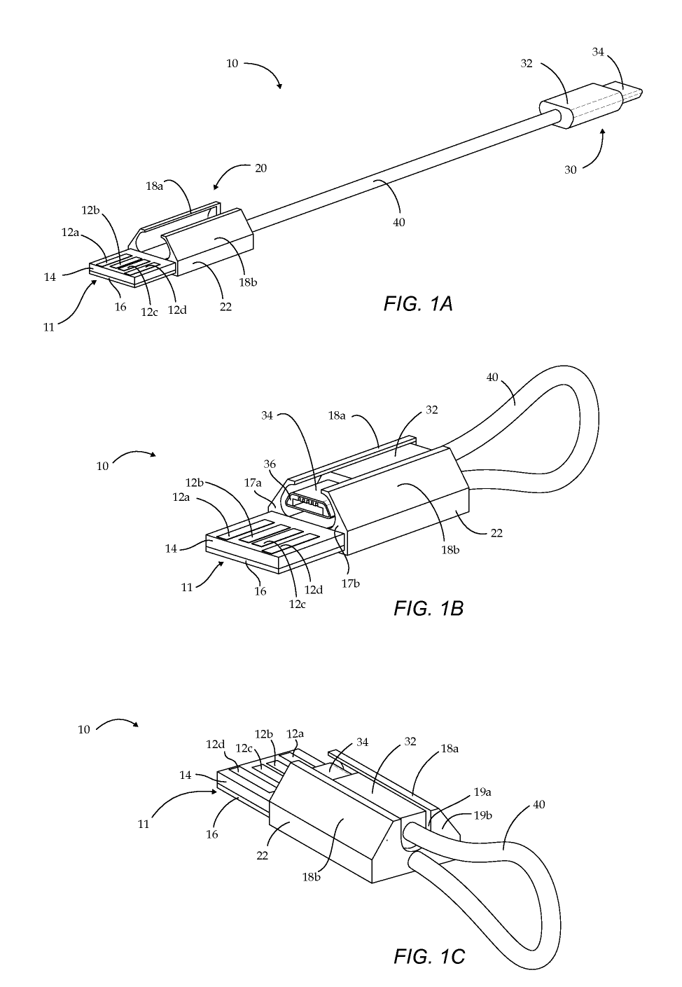

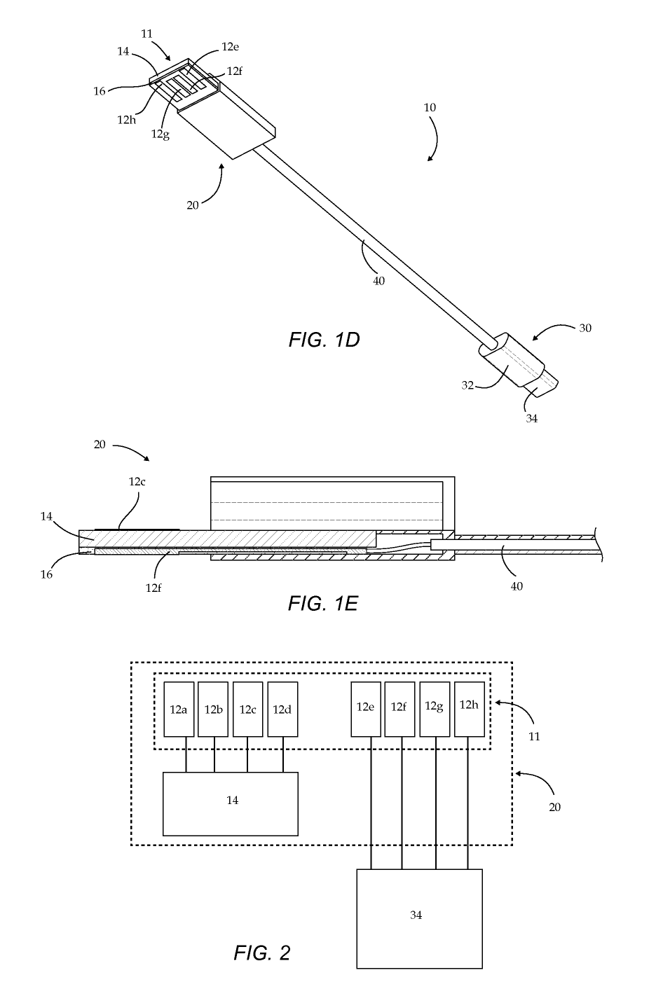

With reference to FIG. 1A-1D, which are simplified perspective views, respectively, of a data storage/transfer device 10 according to one embodiment of the present invention. The embodiment comprises a main body 20, a cable 40 and a second connector 30. A data storage component 14 and a supporting block 16 extend longitudinally away from a housing 22 in a direction parallel to the length of main body 20. Data storage component 14 may be a memory card reader or an integrated memory chip to allow users to access and/or storage data. Data storage component 14 includes contacts for Vcc (power), GND (ground) and a pair of differential data signals (D+, D−). Data storage component 14 is electrically coupled with a first plurality of contacts 12a-12d shown in FIG. 1A that allow outside devices to communicate with data storage component 14. Main body 20 comprises a tongue 11. Tongue 11 functions as a first connector head to mate with other receptacle connectors. In this particular embodiment, tongue 11 is shaped to become a connector head that can fit into the cavity defined by the inner surface of a standard USB receptacle connector, more specifically, a standard USB Type A receptacle connector. On the bottom of tongue 11 as shown in 1D, there is a second plurality of contacts 12e-12h. Contacts 12e-12h may be insert molded to form a supporting block 16. Supporting block 16 is made from dielectric material. The supporting block 16 may be securely attached to data storage component 14 to define the thickness of tongue 11. Second connector 30, preferably, may include a second connector head 34 which can correspond to a different type of receptacle connector than tongue 11 does, e.g., a Micro USB or Lightning connectors. Second connector head 34 includes contacts for Vcc (power), GND (ground) and a pair of differential data signals (D+, D−). In some embodiments, second connector head 34 may include additional contacts for special modes, such as OTG host mode.

FIG. 1E is a simplified cross sectional view of a main body 20 according to one particular embodiment of the present invention as shown in FIG. 1A-1D. FIG. 2 is a schematic representation of connections between contacts 12a-12h, data storage component 14 and a second connector head 34 according to one particular embodiment of the present invention as shown in FIGS. 1A-1E. As shown in FIG. 1E and FIG. 2, first plurality of contacts 12a-12d is electrically coupled with data storage component 14, and second plurality of contact 12e-12h is electrically coupled with second connector 30 via cable 40. First plurality of contacts 12a-12d and second plurality of contact 12e-12h are positioned on tongue 11 to have 180 degree symmetrical pinouts such that first or second plurality of contacts may be operatively coupled with a corresponding receptacle connector depending on which orientation tongue 11 is inserted into that receptacle connector with. When first plurality of contacts 12a-12d of tongue 11 is coupled with a corresponding receptacle connector, data storage/transfer device 10 may function as a flash drive. When second plurality of contact 12e-12h of tongue 11 is coupled with a corresponding receptacle connector and second connector 30 couples with another corresponding receptacle connector, data storage/transfer device 10 may allow bidirectional data and/or power transfer between these two receptacle connectors.

As with USB connectors, first and second plurality of contacts 12a-12d and 12e-12h includes contacts for Vcc (power), GND (ground) and a pair of differential data signals (D+, D−). For example, contact 12a may a GND (ground) pin, contact 12b may be a D+ (data+) pin, contact 12c may be a D− (data−) pin and contact 12d may be a Vcc (power) pin.

Second connector 30 is allowed to be folded backward and securely but releasably attached to main body 20, for the purpose of reducing the total length of the embodiment. FIGS. 1A and 1D show one embodiment in a extended state. FIG. 1B-1C show one embodiment in a folded state. As shown in FIGS. 1A-1C, housing 22 includes connector holders 18a-18b which define a cavity that can fit in second connector 30, an opening 19a (shown in FIG. 1C) which allows cable 40 to pass through, a stopper 19b (shown in FIG. 1C) that stops second connector 30 from sliding out backward. Accordingly, when second connector 30 is fully inserted, the distal end 36 of second connector head 34 may be against or behind the plane which is define by surface 17a and 17b. In other words, second connector 30 may not intercept with the plane which is define by surfaces 17a and 17b. The purpose is to reduce the possibility of interference caused by second connector head 34 when inserting tongue 11 into a corresponding receptacle connector.

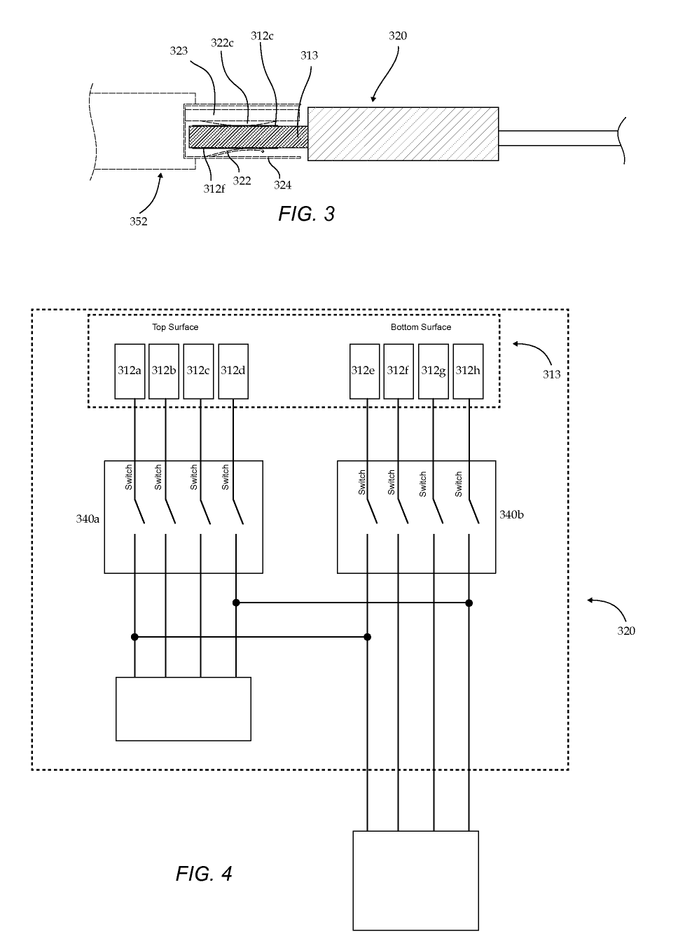

FIG. 3 is a simplified cross sectional view of a main body 320 of another embodiment of the present invention partially plugging into a first corresponding receptacle connector 352. Receptacle connector 352 may be a USB connector. FIG. 4 is a schematic representation of the connections between contacts 312a-312h, protection circuits 340a-340b, a data storage component 314 and a second connector head 334 according to one embodiment of the present invention. Main body 320 of this embodiment is similar to embodiments described above, e.g., main body 20. As shown in FIG. 3, tongue 313 of main body 320 of one embodiment of the present invention acts as a connector mating with a first corresponding receptacle connector 352. Data storage component 314 may be a memory card reader or an integrated memory chip to allow users to access and/or storage data. Data storage component 314 includes contacts for Vcc (power), GND (ground) and a pair of differential data signals (D+, D−). Second connector head 334 includes contacts for Vcc (power), GND (ground) and a pair of differential data signals (D+, D−). In some embodiments, second connector head 334 may include additional contacts for special modes, such as OTG host mode. As shown in FIG. 4, tongue 313 includes a first plurality of contacts 312a-312d on top side that is coupled with data storage component 314, and a second plurality of contact 312e-312h on bottom side that is coupled with second connector head 334. However, contacts 312a and 312e are coupled with each other and may act as GND pins, contact 312d and 312h are coupled with each other and may act as Vcc pins. Accordingly, when first plurality of contact 312a-312d are also coupled with a first receptacle connector, e.g., a USB port (receptacle connector), second connector head 334 also receives power supply but no data transmission from the first corresponding receptacle connector. Therefore, when this particular embodiment of the present invention is used as a flash drive, second connector head 334 can still receive power from the first receptacle connector for charging.

As shown in FIG. 3, the corresponding receptacle connector 352, where the tongue 313 is inserted into, may have a conductive metal shell 324. Shell 324 may include conductive metal strip springs 322 which push tongue 313 against block 323 such that contact 322a-322d (FIG. 3 only shows contact 322c) of the corresponding receptacle connector 352 can be coupled with a first plurality of contacts 312a-312d (only contact 312c is shown) on top side of tongue 313. In some situations, conductive metal strip springs 322 of shell 324 may be in contact with a second plurality of contacts 312e-312h (only contact 312f is shown) on the bottom side of tongue 313 and short of some or all of said contacts. Since contacts for Vcc and GND on both side of tongue 313 are coupled, either side of the Vcc contacts can short a GND contact, and may cause potential danger. In some situations, shell 324 is grounded, therefore when in contact with only Vcc contacts, it may still cause a short circuit. To avoid such danger described above, protection circuits 340a and 340b may be added between two plurality of contacts and the rest of the circuit as shown in FIG. 4. Protection circuits 340a-340b will insulate shorted contacts from the rest of the circuit. For example, as shown in FIG. 3 if contact 312a-312d(only contact 312c is shown) are coupled with a receptacle connector 352 and contacts 312e-312h (only contact 312c is shown) are shorted because of a conductive shell 324, protection circuit 340b will switch off contact 312e-312h. Therefore, data storage component 314 in FIG. 4 can still work and power can still be delivered to second connector head 334 in FIG. 4.

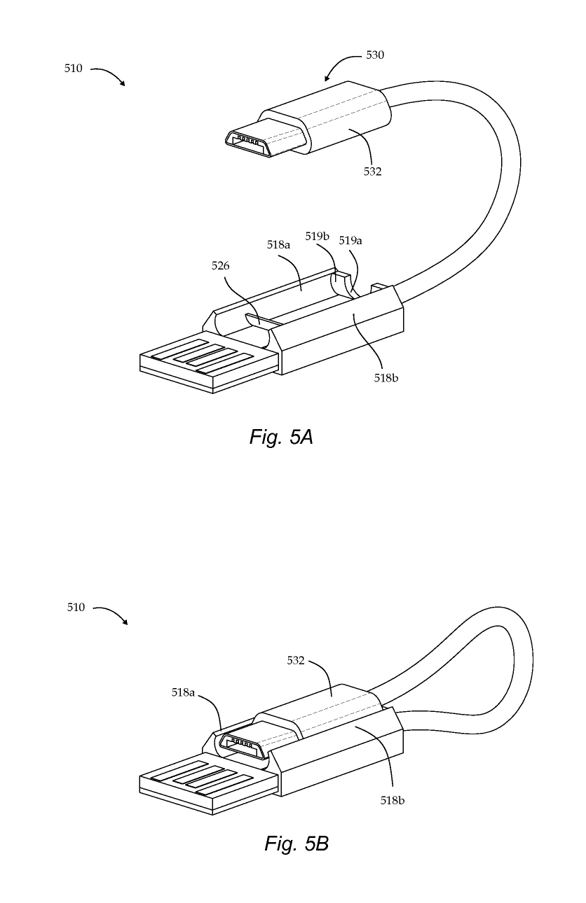

FIGS. 5A-5B are simplified perspective views, respectively, of a data storage/transfer device 510 according to still another embodiment of the present invention. In FIG. 5A-5B, data storage/transfer device 510 is similar to embodiments described above, e.g., data storage/transfer device 10 in FIGS. 1A-1D. However, connector holders 518a-518b may have lower profiles and the top edges bend less inward compared to embodiment in FIGS. 1A-1D. A stopper 519b and a secondary stopper 526 define a distance that can fit in the length of connector body 532. Connector holders 518a-518b may be made from resilient material so that second connector 530 can easily snap from the top into a cavity defined by the inner surfaces of connector holders 518a-518b, stopper 519b and secondary stopper 526.

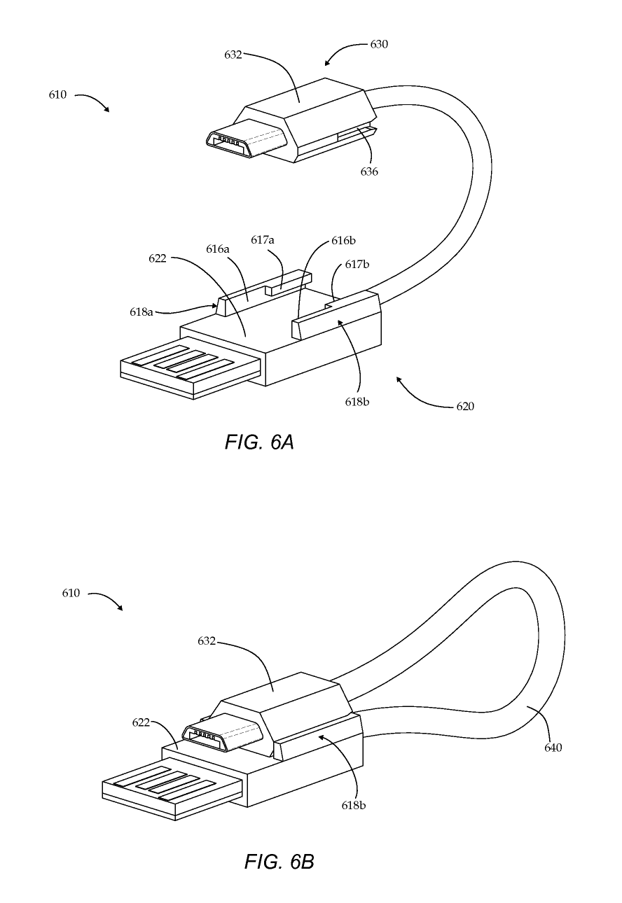

FIGS. 6A-6B are simplified perspective views, respectively, of a data storage/transfer device 610 according to still another embodiment of the present invention. In FIG. 6A-6B, data storage/transfer device 610 is similar to embodiments described above, e.g., data storage/transfer device 10 in FIG. 1A-1D. However, as shown in FIG. 6A, connector holders 618a-618b include surfaces 616a-616b which restrain horizontal movement parallel to the width of main body 620. Extrusions 617a-617b can be inserted into cavities 636 (only cavity 636 one side is shown) of connector body 632. To attach connector body 632 on to main body 620, users may align connector body 632 with main body 620 utilizing surface 622 and surfaces 616a-616b then push it backward into a state shown in FIG. 6B.

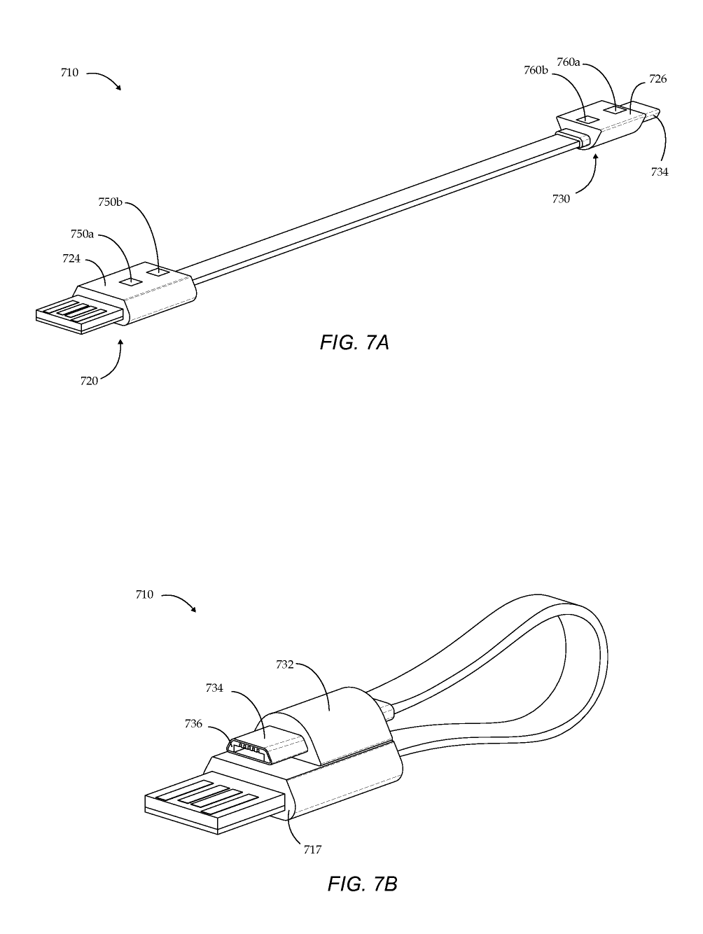

FIGS. 7A-7B are simplified perspective views, respectively, of a data storage/transfer device 710 according to still another embodiment of the present invention. Data storage/transfer device 710 is similar to embodiments described above, e.g., data storage/transfer device 10 in FIG. 1A-1D. However, as shown in FIG. 7A, a main body 720 includes a flat surface 724 corresponding with flat surface 726 on second connector 730. A first plurality of magnets 750a-750b are on flat surface 724 which correspond to a second plurality of magnets 760a-760b on surface 726. In some embodiments of the present invention, magnets 750a-750b may be hidden beneath surface 724 and magnets 760a-760b may be hidden beneath flat surface 726. When second connector 730 is folded back against main body 720, they will attract each other together by magnets 750a-750b and 760a-760b. Similar to embodiments described above, e.g., data storage/transfer device 10 in FIG. 1A-1D, when second connector 730 is attached to main body 720, the distal end 736 of second connector head 734 may be against or behind the plane which is define by surface 717 as shown in FIG. 7B.

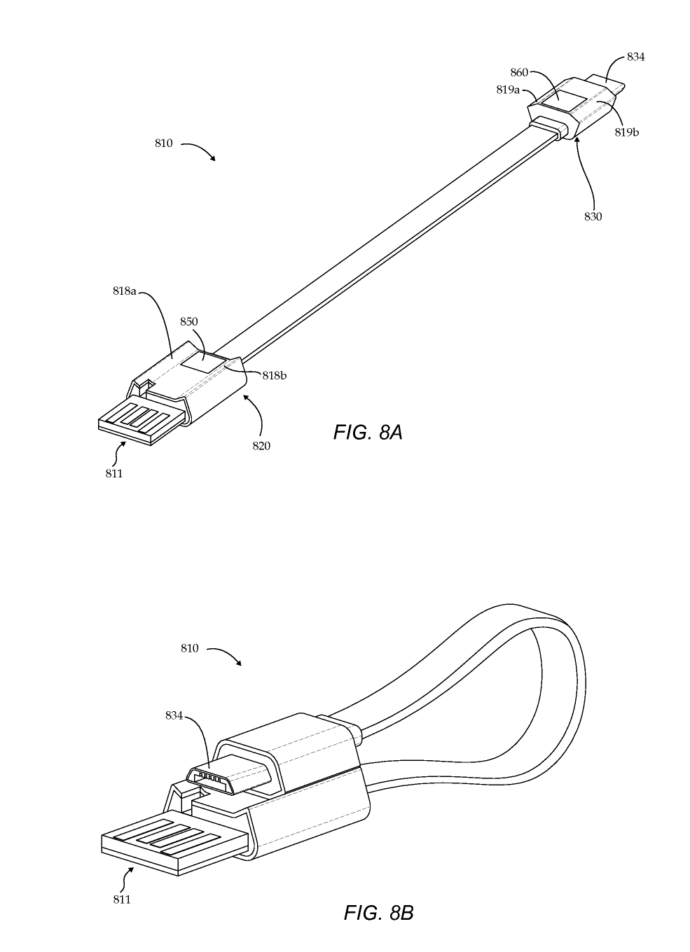

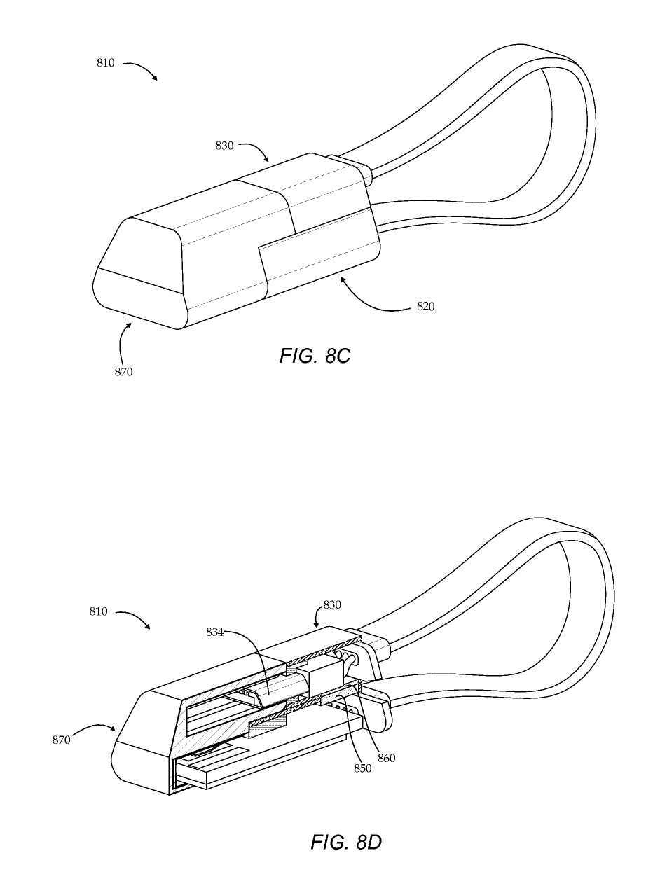

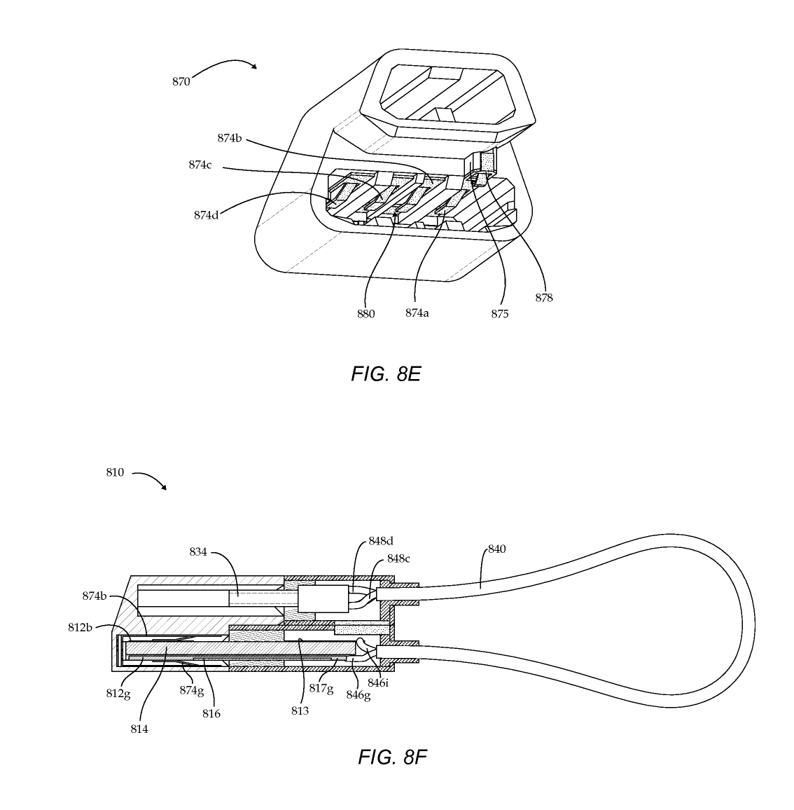

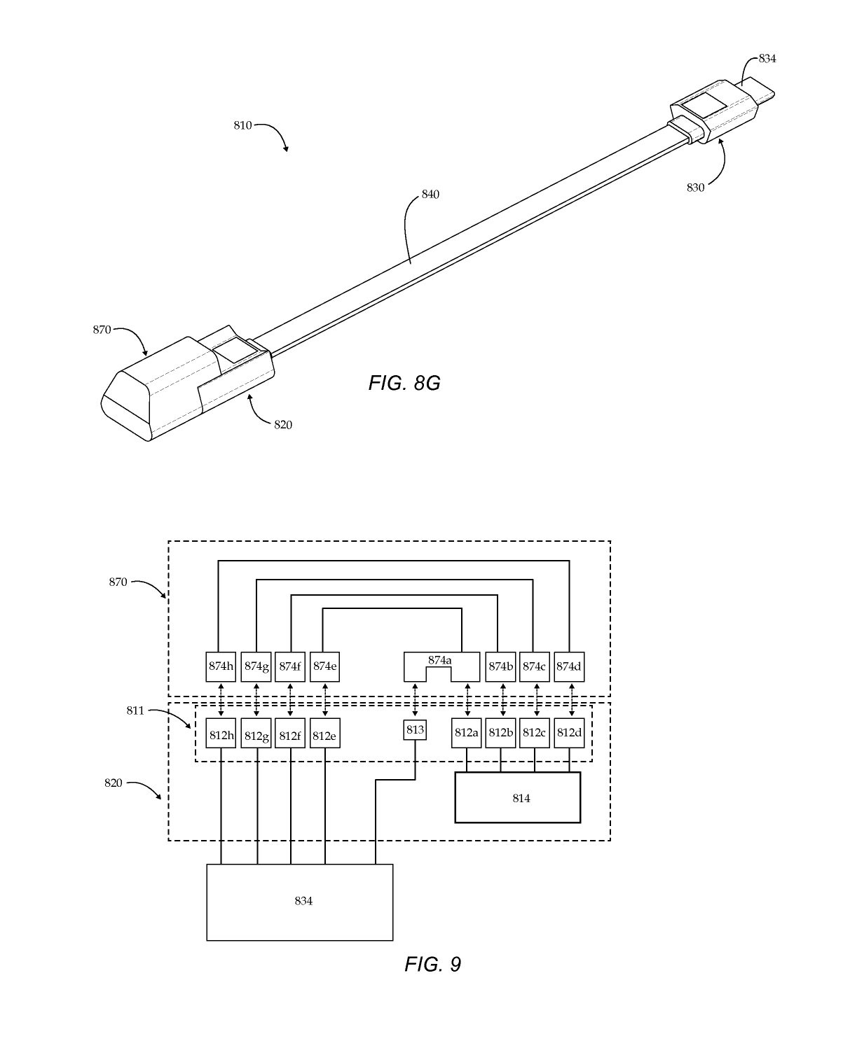

FIGS. 8A-8B are simplified perspective views, respectively, according to still another embodiment of the present invention without a cap 870 which is shown in FIGS. 8C-8E. This embodiment is similar to embodiments described above, e.g., data storage/transfer device 710 in FIGS. 7A-8B. However, main body 820 of data storage/transfer device 810 includes guiding surfaces 818a-818b corresponding to guiding surface 819a-819b of second connector 830, which guide second connector 830 into a designated position when second connector 830 is folded back against main body 820. When data storage/transfer device 810 is folded as shown in FIG. 8B, main body 820 and second connector 830 will attract each other together by magnets 850 and 860. As shown in FIG. 8C, cap 870 is used to protect first and second connector heads and further secure the folded state of the embodiment. FIG. 8D shows the relationship described above in a cross sectional perspective view.

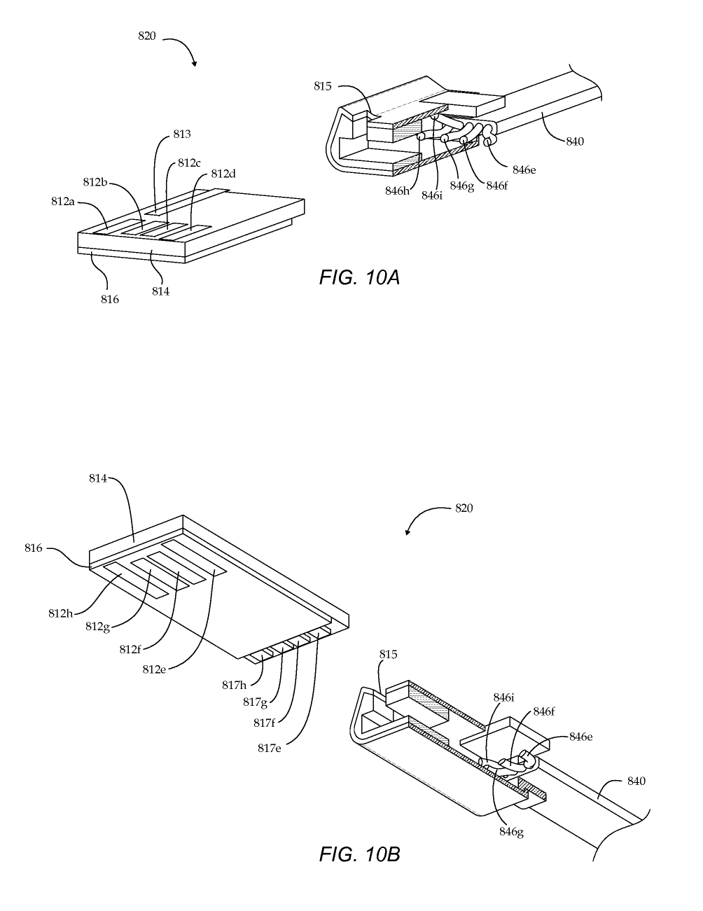

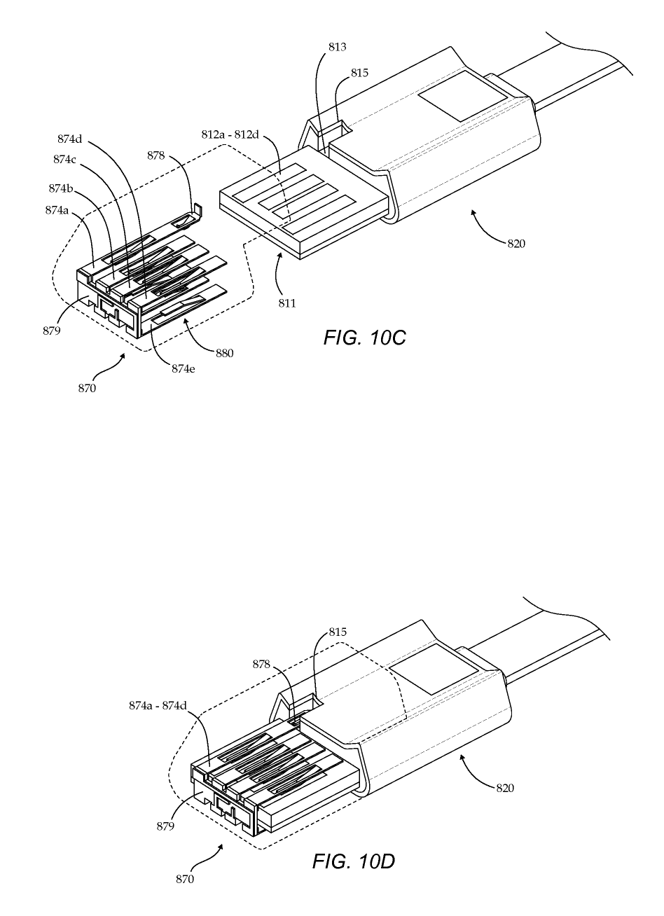

FIGS. 10A-10B are simplified cross sectional exploded perspective views, respectively, of main body 820. In FIG. 10A showing the front top view, a first plurality of contacts 812a-812d couple with a data storage component 814; contact 813 couples with wires 846i from cable 840. Data storage component 814 may be a memory card reader or an integrated memory chip to allow users to access and/or storage data. Data storage component 814 includes contacts for Vcc (power), GND (ground) and a pair of differential data signals (D+, D−). Second connector head 834 includes contacts for Vcc (power), GND (ground) and a pair of differential data signals (D+, D−). In some embodiments, second connector head 834 may include additional contacts for special modes, such as OTG host mode Cavity 815 will reveal contact 813 after parts are fully assembled. In FIG. 10B showing the front bottom view, a second plurality of contacts 812e-812h, which are partially embedded into supporting block 816, have their tips 817e-817h exposes from one end of supporting block 816, which are welded or soldered to wires 846e-846h from cable 840. FIG. 8F shows the relationship described above in a cross section view.

Data storage/transfer device 810 may include an OTG ID contact in one of the connectors, e.g., a Micro USB connector. When an OTG ID contact of a connector is grounded, then means that that connector is on host mode, and consequently turns on the host mode of a OTG supported outside device that directly connects to it. Second connector head 834 may be a Micro USB connector head and tongue 811 (shown in FIGS. 8A-8B) may be a USB connector head. As shown in FIG. 8C-8G, data storage/transfer device 810 may use cap 870 to act as an OTG switch. FIG. 8G shows a state that cap 870 is attached with main body 820 such that OTG flash drive mode is turned on. In this embodiment, when Data storage/transfer device 810 is in OTG flash drive mode, it may correspond to an outside device via second connector head 834. If a user connects outside devices to both tongue 811 (shown in FIGS. 8A-8B) and second connector head 834 when in OTG flash drive mode, it may cause problems with the outside devices. The advantage of using cap 870 as OTG switch to turn on OTG flash drive mode and block tongue 811 (shown in FIGS. 8A-8B) of main body 820 from plugging into a receptacle connector is that, an outside device may correspond exclusively to second connector head 834, therefore, a user cannot connect an outside device to a wrong connector and confuse the device (foolproof purpose).

As shown in FIG. 8E, cap 870 may include a switch structure 880 (installed in the lower cavity of tongue reception) that has contacts 874a-874h (contacts 874e-874h are not shown) and a PCB (Printed circuit board) 879 (not shown). FIG. 9 is a schematic representation of the connection between contacts 812a-812h, contact 813, data storage component 814 of main body 820, contacts 874a-874h of cap 870, and a second connector head 834. Contacts 812a and 812e are GND pins; contacts 812b and 812f are D+ pins; contacts 812c and 812g are D− pins; contacts 812d and 812h are Vcc pins; contact 813 are an OTG ID pin. When cap 870 is attached to main body 820, contacts 812a, 812e, 813, 874a and 974e are coupled; contacts 812b, 812f, 874b and 974f are coupled; contacts 812c, 812g, 874c and 874g are coupled; contacts 812d, 812h, 874d and 874h are coupled. Therefore, contact 813 is grounded and turn on OTG host mode since contact 812a and 812e are GND pins. Then when second connector head 834 with a grounded OTG ID contact 813 is inserted into a corresponding receptacle connector of an OTG supported outside device, this outside device will be identified as a host device. Outside devices, e.g., a mobile phone, may then act as a host to read/write data on data storage component 814 of data storage/transfer device 810 via second connector head 834.

FIGS. 10C-10D are partially transparent simplified perspective views, respectively, of main body 820 and switch structure 880 of cap 870. FIGS. 10C-10D show how switch structure 880 of cap 870 makes contact with contacts 812a-812h (812e-812h are not shown) and contact 813. When inserted, contact 874a couples with both contact 812a and 813. Contact 874a has a tip 878 on extrusion 875 (shown in FIG. 8E), which is inserted into cavity 815.

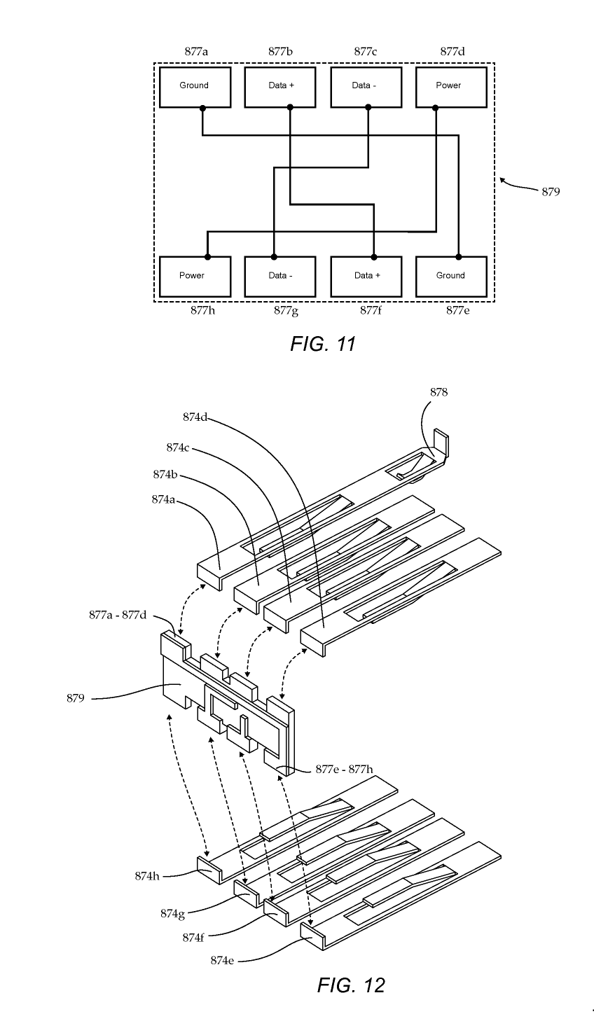

FIG. 11 is a schematic representation of PCB 879 of switch structure 880 shown in FIG. 10C. FIG. 12 is an exploded perspective view of switch structure 880. Contacts 874a-874h are respectively welded or soldered, which are represented in dash lines, to designated fingers 877a-877h. Similar to embodiments described above, as shown in FIGS. 8A-8B, contacts 812a-812h that include GND, D+, D− and Vcc pins, are positioned on tongue 811 to have 180 degree symmetrical pinouts. Therefore, in FIG. 11, a first plurality of fingers 877a-877d and second plurality of fingers 877e-877h also have 180 degree symmetrical pinouts to match pinouts of contacts 812a-812h. Finger 877a is coupled with 877e for ground (GND); finger 877b is coupled with 877f be for data+(D+); finger 877c is coupled with 877g for date—(D−); finger 877d is coupled with 877h for power (Vcc).

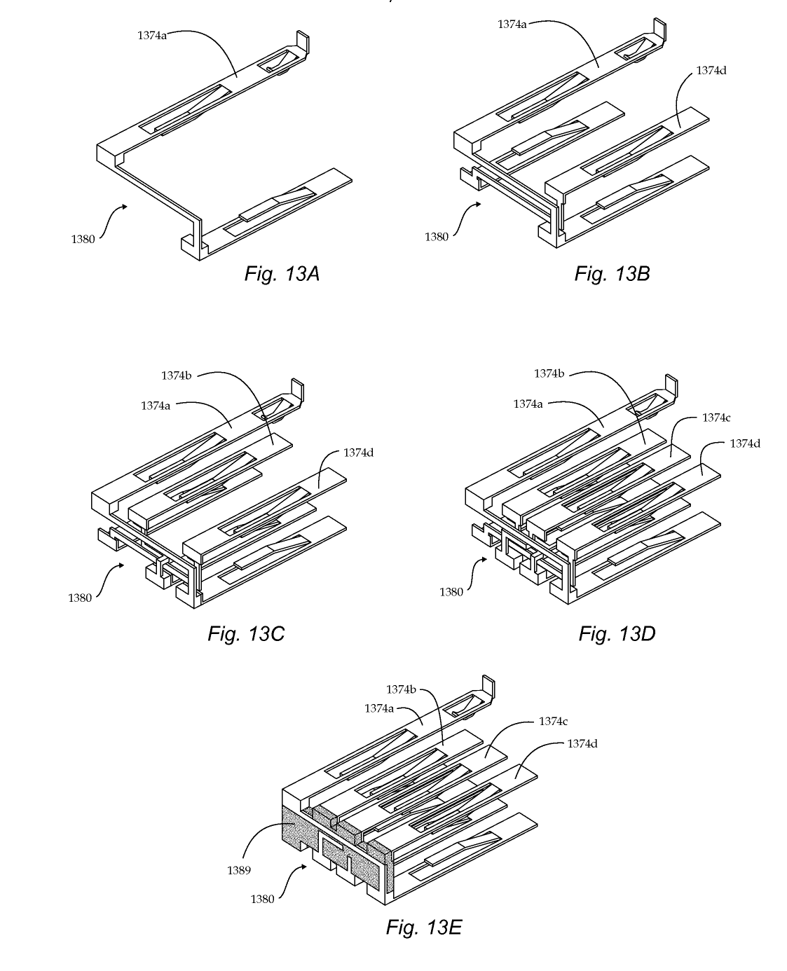

FIG. 13A-13E are the simplified perspective views of contact frames 1374a-1374d of a switch structure 1380 in various stages of manufacture according still another embodiment of the present invention, respectively, in their positions with respect to each other. Switch structure 1380 functions similarly as switch structure 880 described above. However, instead of using eight contacts that welded or soldered to fingers of PCB 879, switch structure 1380 include four C-shape contacts 1374a-1374d partially embedded in a dielectric support 1389.

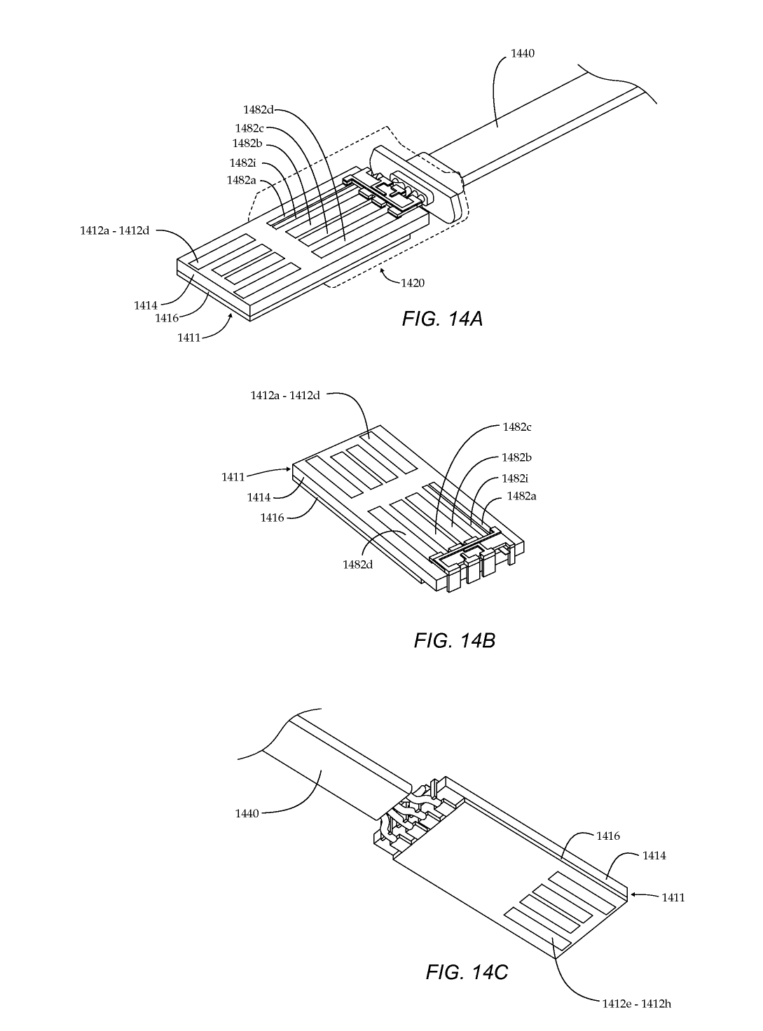

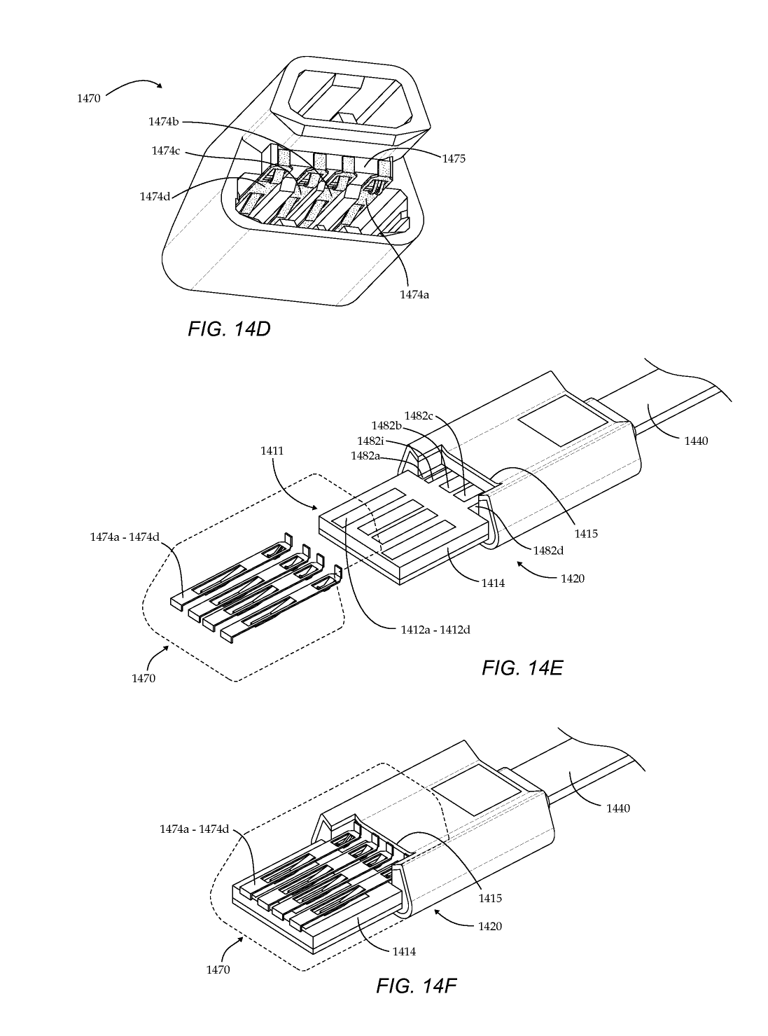

FIGS. 14A-14C are simplified perspective front top, back top and back bottom views, respectively, of a main body 1420 of a data storage/transfer device in various stage of manufacture according still another embodiment of the present invention. Main body 1420 is similar to embodiments above, e.g., main body 820. However, even though the schematics of this embodiment is similar to the schematic representation in FIG. 9, the structure of the contacts that are used to turn on OTG host mode is not identical to previous embodiments. In FIGS. 14A-14B, a first plurality of contacts 1412a-1412d are coupled with data storage component 1414. In FIG. 14C, contacts 1412e-1412h are on a supporting block 1416. Contact 1482a is coupled with contact 1412e for GND; contact 1482b is coupled with contact 1412f for D+; contact 1482c is coupled with contact 1412g for D−; contact 1482d is coupled with contact 1412h for Vcc, contact 1482i is an OTG ID pin.

As shown in FIG. 14D, a cap 1470 may have a plurality of contacts 1474a-1474d installed in the lower cavity of tongue reception. Contacts 1474a-1474d extend out on extrusion 1475, which may be inserted into cavity 1415 (shown in FIG. 14E-14F). As shown in FIG. 14E-14F, when cap 1470 is attached to a main body 1420 for OTG function, contact 1474a will couple contacts 1412a, 1482a and 1482i (Contact 1482i a OTG ID contact then be grounded with contacts 1412a and 1482a to turn on OTG function); contact 1474b will couple contacts 1412b and 1482b; contact 1474c will couple contacts 1412c and 1482c; contact 1474d will couple contacts 1412d and 1482d. Therefore, outside device may communicate with data storage component 1414 via a second connector on the other end of cable 1440.

In some embodiments of the present invention, a host mode may be activated by other mechanisms or software instead of USB OTG. For example, a software installed on a mobile phone and/or embodiments of the present invention, which allows the mobile phone to read/write data on the data storage component of the present invention.

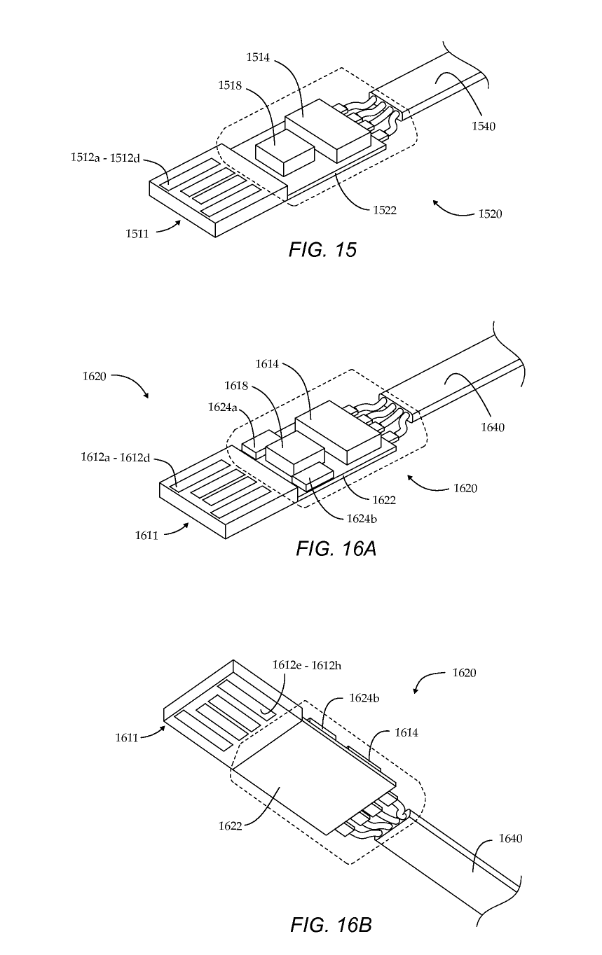

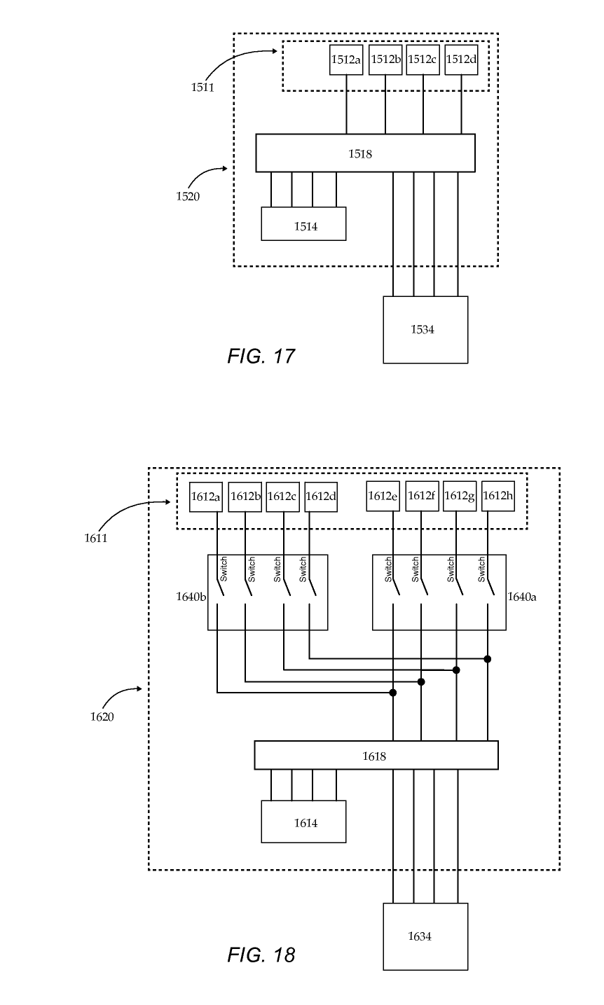

FIG. 15 is a partially transparent simplified perspective view of a main body 1520 of a data storage/transfer device according to still another embodiment of the present invention. FIG. 17 is a schematic representation of the connections between a plurality of contacts 1512a-1512d, a USB hub controller 1518, a data storage component 1514 and a second connector head 1534 according to one particular embodiment of the present invention shown in FIG. 15. Data storage component 1514 may be a memory card reader or an integrated memory chip to allow users to access and/or storage data. Data storage component 1514 includes contacts for Vcc (power), GND (ground) and a pair of differential data signals (D+, D−). Second connector head 1534 includes contacts for Vcc (power), GND (ground) and a pair of differential data signals (D+, D−). In some embodiments, second connector head 1534 may include additional contacts for special modes, such as OTG host mode. As shown in FIG. 15, this embodiment includes a tongue 1511 with a plurality of contacts 1512a-1512d that corresponds to a receptacle connector, e.g., a standard USB receptacle connector. Contacts 1512a-1512d are coupled with a PCB 1522 which includes a USB hub controller 1518 and a data storage component 1514. PCB 1522 is also coupled with a second connector via a cable 1540. As shown in FIG. 17, when tongue 1511 functions as a first connector head and is coupled into a first outside device, e.g., a computer, this first outside device may become a host. USB hub controller 1518 may allow both data storage component 1514 and a second outside device that is connected to a second connector head 1534 to correspond to the host device at the same time via a plurality of contacts 1512a-1512d.

FIGS. 16A-16B are partially transparent simplified perspective front top, front bottom views, respectively, of a main body 1620 of a data storage/transfer device according to still another embodiment of the present invention. FIG. 18 is a schematic representation of the connection between a first plurality of contacts 1612a-1612d, a second plurality of contacts 1612e-1612h, protection circuits 1640a-1640b, a USB hub controller 1618, a data storage component 1614 and a second connector head 1634 according to one particular embodiment of the present invention shown in FIGS. 16A-16B. Data storage component 1614 may be a memory card reader or an integrated memory chip to allow users to access and/or storage data. Data storage component 1614 includes contacts for Vcc (power), GND (ground) and a pair of differential data signals (D+, D−). Second connector head 1634 includes contacts for Vcc (power), GND (ground) and a pair of differential data signals (D+, D−). In some embodiments, second connector head 1634 may include additional contacts for special modes, such as OTG host mode. This embodiment is similar to the previous embodiment shown in FIG. 15 and FIG. 17. However, this embodiment has a first plurality of contacts 1612a-1612d on top surface of tongue 1611 (shown in FIG. 16A) and a second plurality of contacts 1612e-1612h (shown in FIG. 16B) on bottom surface of tongue 1611. The first and second plurality of contacts have 180 degree symmetrical pinouts such that first or second plurality of contacts can be operatively coupled with a corresponding receptacle connector in either orientations. As shown in FIG. 18, the first and second plurality of contacts 1612a-1612d and 1612e-1612h are both coupled with dUSB hub controller 1618 such that the embodiment of the present invention can operatively have the same function regardless the orientation of the tongue insertion. Similar to one particular embodiment described above, e.g., main body 320 in FIG. 3 and FIG. 4, main body 1620 may include protection circuits 1640a-1640b to reduce the potential short circuit danger caused by a grounded shell of a corresponding receptacle connector. If any of the contacts are shorted by a conductive shell of a receptacle connector, protection circuits will insulate these contacts from the rest of the circuit and allow other contacts to continue operating.

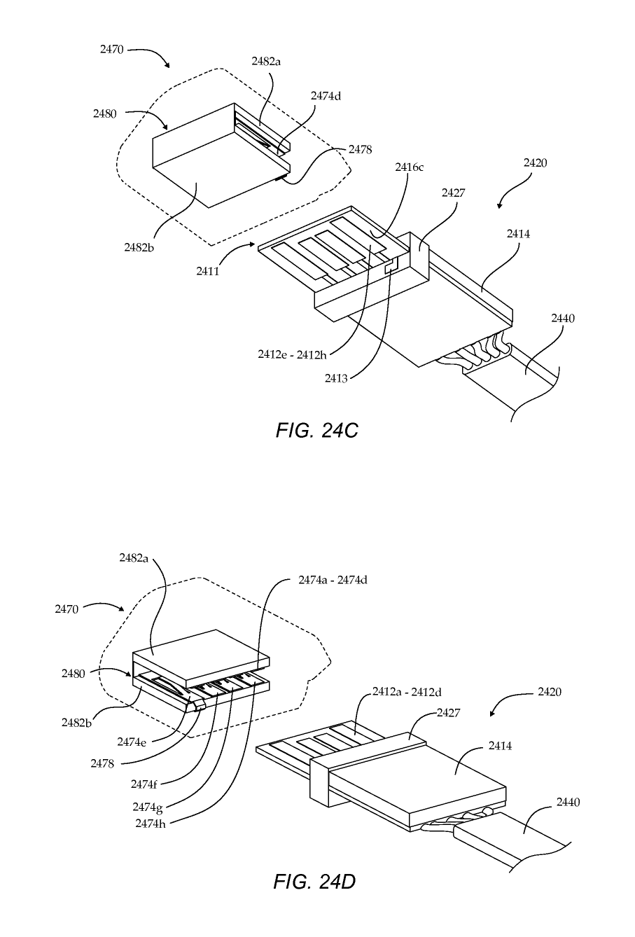

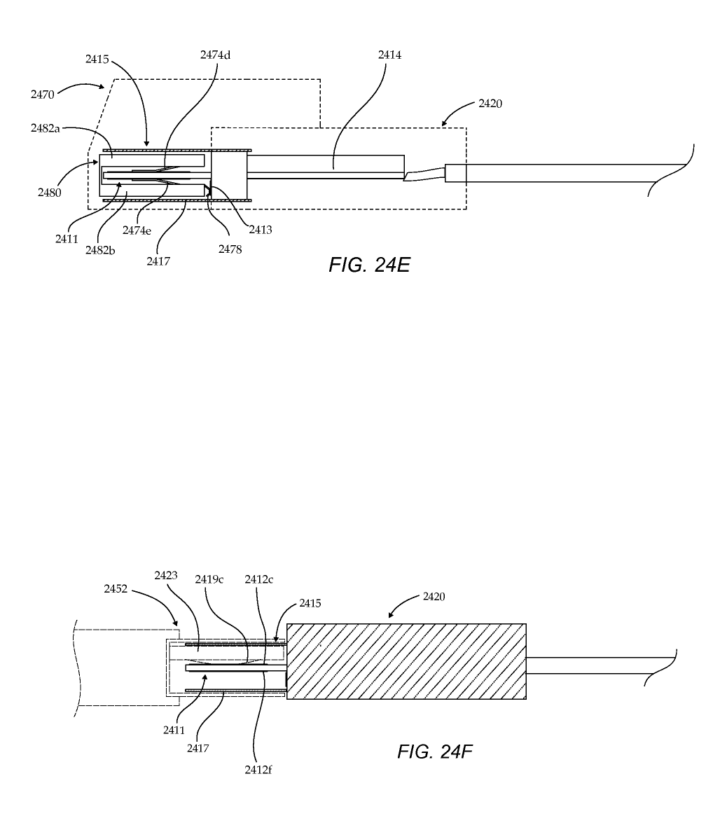

FIG. 24A is a simplified perspective view, of a main body 2420 and a cap 2470 of a data storage/transfer device, according to still another embodiment of the present invention. This embodiment is similar to the embodiments described in FIGS. 8A-8G, FIG. 9, FIGS. 10A-10D, FIG. 11, FIG. 12 and FIGS. 13A-13E. However, as shown in FIG. 24A, first connector head 2415 of this embodiment includes a metal shell 2417 and a tongue 2411. Tongue 2411 is significantly thinner than tongues of some embodiments described above, e.g., tongue 811 in FIGS. 8A-8B. Tongue 2411 is in the center of the space defined by the inner surfaces of metal shell 2417.

FIGS. 24B-24D are partially transparent simplified perspective views of the front top, front bottom, back top, respectively, of main body 2420 and switch structure 2480 of cap 2470 of said embodiment. FIG. 26 is a schematic representation of the connections between contacts 2412a-2412h, contacts 2474a-2474h, OTG ID contact 2413, data storage component 2414 and a second connector head 2434 of said embodiment. Data storage component 2414 may be a memory card reader or an integrated memory chip to allow users to access and/or storage data. Data storage component 2414 includes contacts for Vcc (power), GND (ground) and a pair of differential data signals (D+, D−). Second connector head 2434 includes contacts for Vcc (power), GND (ground) and a pair of differential data signals (D+, D−). In some embodiments, second connector head 2434 may include additional contacts for special modes, such as OTG host mode. As shown in FIGS. 24B-24D, there is a first plurality of contacts 2412a-2412d on a first surface 2416a of tongue 2411 (shown in FIG. 24B) and a second plurality of contacts 2412e-2412h (shown in FIG. 24C) on a second surface 2416b of tongue 2411. OTG ID contact (shown in FIG. 24C) is on a supporting structure 2427 that extends longitudinally away from tongue 2411 in a direction perpendicular to first surface 2416a and second surface 2416b of tongue 2411. First plurality of contacts 2412a-2412d are coupled with data storage component 2414. Second plurality of contacts 2412e-2412h and OTG ID contact 2413 are coupled with second connector head 2434 (shown in FIG. 26) via a cable 2440. First and second plurality of contacts 2412a-2412d and 2412e-2412h may include contacts for Vcc, GND and a pair of differential data signals (D+, D−). For example, in first plurality, contact 2412a is for data storage component's GND, contact 2412b is for data storage component's D+, contact 2412c is for data storage component's D- and contact 2412d is for data storage component's Vcc, and in second plurality, contact 2412e is for cable's GND, contact 2412f is for cable's D+, contact 2412g is for cable's D− and contact 2412h is for cable's Vcc. The supporting structure of tongue 2411 may be a PCB (Printed Circuit Board) or a piece of plastic. The first connector head 2415 (shown in FIG. 24A) of main body 2420 has a dual or double orientation design which enables the first connector head 2415 to be inserted into a corresponding receptacle connector in either of two intuitive orientations, which is similar to tongue 11 shown in FIGS. 1A-1E.

FIG. 24F is a simplified cross sectional view of a first connector head 2415 of said embodiment (shown in FIG. 24A), while plugged into a corresponding standard USB Type A receptacle connector 2452. Metal shell 2417 of main body 2420 can be inserted into the cavity of receptacle connector 2452. When the first connector head 2415 (shown in FIG. 24A) of main body 2420 mate with corresponding receptacle connector 2452, a plurality of contacts 2419a-2419d (only contact 2419c is shown) of tongue 2423 of connector 2452 is in contact with first or second plurality of contacts on either the first or second surface of tongue 2411, depending on which orientation the said first connector head 2415 is inserted into, to correspond to different functions of the present invention. For example, if the first plurality of contacts 2412a-2412d of the first connector head 2415 corresponds to a receptacle connector, it may make the embodiment function as a flash drive; on the other hand, if a second plurality of contacts 2412e-2412h of first connector head 2415 corresponds to a receptacle connector, it may make the embodiment functions as a USB cable.

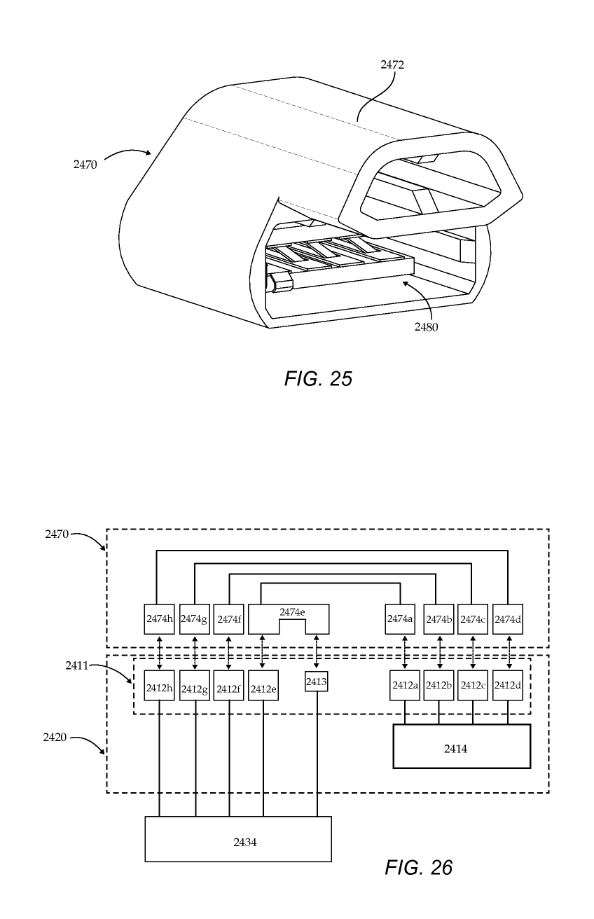

FIG. 25 is a simplified perspective view of a cap 2470 of said embodiment. As shown in FIGS. 24B-24E and FIG. 25, switch structure 2480 resides in a cavity of cap 2470 that can fit into the first connector head 2415 (shown in FIG. 24A). Switch structure 2480 is similar to embodiments shown in FIGS. 10C-10D. FIG. 11, FIG. 12 and FIGS. 13A-13E. However, as shown in FIGS. 24B-24D, switch structure 2480 has a first plurality of contact 2474a-2474d on a first tongue 2482a and a second plurality of contact 2474e-2474h on a second tongue 2482b. As shown in FIG. 26, contact 2474a is coupled with contact 2474e; contact 2474b is coupled with contact 2474f, contact 2474c is coupled with contact 2474g; contact 2474d is coupled with contact 2474h. Contact 2474e has a tip 2478 (shown in FIG. 24D) that may be used to couple with OTG ID contact 2413 (shown in FIG. 24C) when the first connector head 2415 (shown in FIG. 24A) is inserted into cap 2470.

FIG. 24E is a simplified cross sectional view of main body 2420 and switch structure 2480 of cap 2470 of a data storage/transfer device when function as an OTG flash drive. When the first connector head 2415 is inserted into cap 2470, the data storage/transfer device is in OTG flash drive mode. The first plurality of contacts 2474a-2474d (only contact 2474d is shown), second plurality of contacts 2474e-2474h (only contact 2474e is shown) and tip 2478 of contact 2474e of switch structure 2480 of cap 2470 may be in contact, respectively, with the first and second plurality of contacts 2412a-2412d, contacts 2412e-2412h and OTG ID contact 2413 of tongue 2411. As shown in FIG. 26, contact 2474a, contact 2474e, contact 2412a, contact 2412e and OTG ID contact 2413 may be coupled; contact 2474b, contact 2474f, contact 2412b and 2412f may be coupled; contact 2474c, contact 2474g, contact 2412c and contact 2412g may be coupled; contact 2474d, contact 2474h, contact 2412d and contact 2412h may be coupled. Contact 2412e is for ground. When OTG ID contact 2413 is coupled with contact 2412e, this embodiment of the present inventions function as an OTG flash drive to allow an OTG supported outside device, e.g., an OTG supported mobile phone, to correspond to data storage component 2414 via second connector head 2434. The advantage of using cap 2470 as OTG switch to turn on OTG flash drive mode and block first connector head 2415 (shown in FIGS. 24A-24B) of main body 2420 from plugging into a receptacle connector is that, an outside device may correspond exclusively to second connector head 2434 (shown in FIG. 26, therefore, a user cannot connect an outside device to a wrong connector and confuse the device (foolproof purpose).

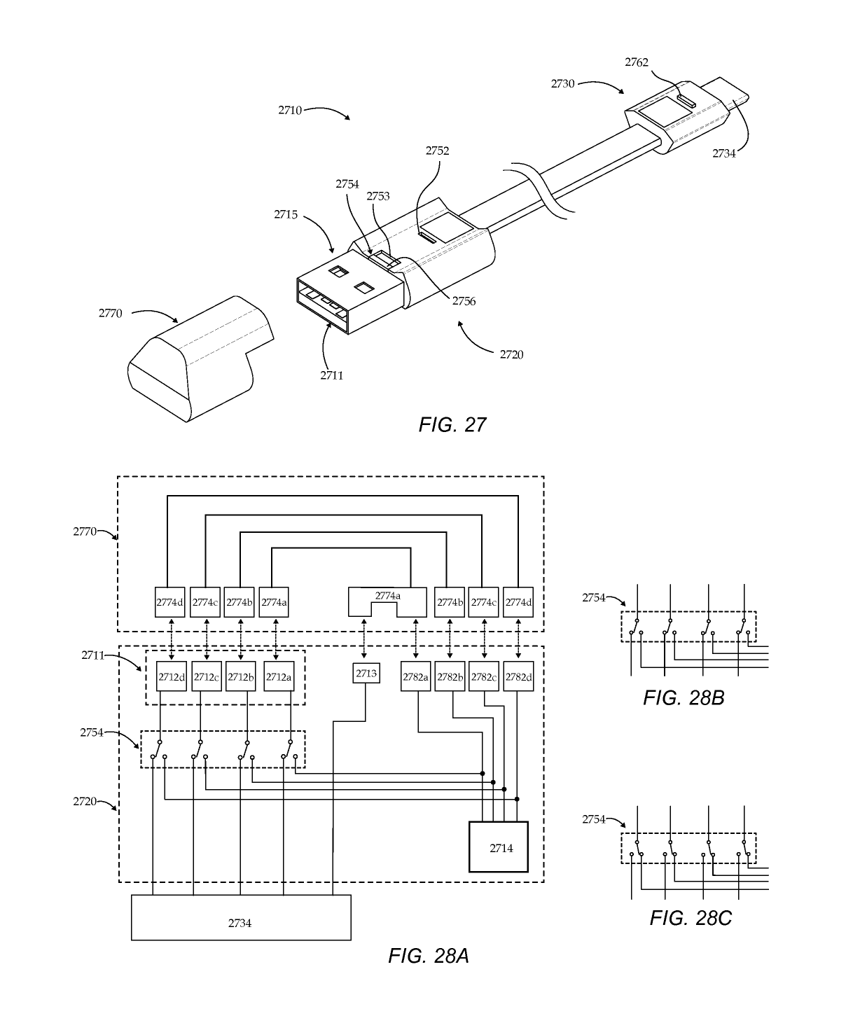

FIG. 27 is a simplified perspective view, of a data storage/transfer device 2710 according to one embodiment of the present invention. This embodiment is similar to embodiments described above, e.g., embodiment in FIG. 24A. However, as show in FIG. 27, first connector head 2715 is a standard USB Type-A connector head and can be plugged into a USB type A receptacle connector with single orientation. A function switch 2754 resides in main body 2720 and partially exposes via opening 2753. A user may slide a switch top 2756 of function switch 2754 back and forth to change the mode of data storage/transfer device 2710 into either USB cable mode or regular flash drive mode. Second connector 2730 has a nub 2762. Main body 2720 has an opening 2752. When data storage/transfer device 2710 folds in a way similar to the embodiment in FIG. 8B, nub 2762 can just fit into the opening 2752 to reduce the possibility of unintentional movement between main body 2720 and second connector 2730.

FIG. 28A is a schematic representation of the connections between contacts 2774a-2774d, contacts 2712a-2712d, contacts 2782a-2782d, an OTG ID contact 2713, function switch 2754, a data storage component 2714 and second connector head 2734 according to said embodiment. Data storage component 2714 may be a memory card reader or an integrated memory chip to allow users to access and/or storage data. Data storage component 2714 includes contacts for Vcc (power), GND (ground) and a pair of differential data signals (D+, D−). Second connector head 2734 includes contacts for Vcc (power), GND (ground) and a pair of differential data signals (D+, D−). In some embodiments, second connector head 2734 may include additional contacts for special modes, such as OTG host mode. In FIG. 28A, function switch 2754 is simplified. Function switch 2754 is a multi-pole, double-throw switch that controls the connections between contacts 2712a-2712d, data storage component 2714 and second connector head 2734.

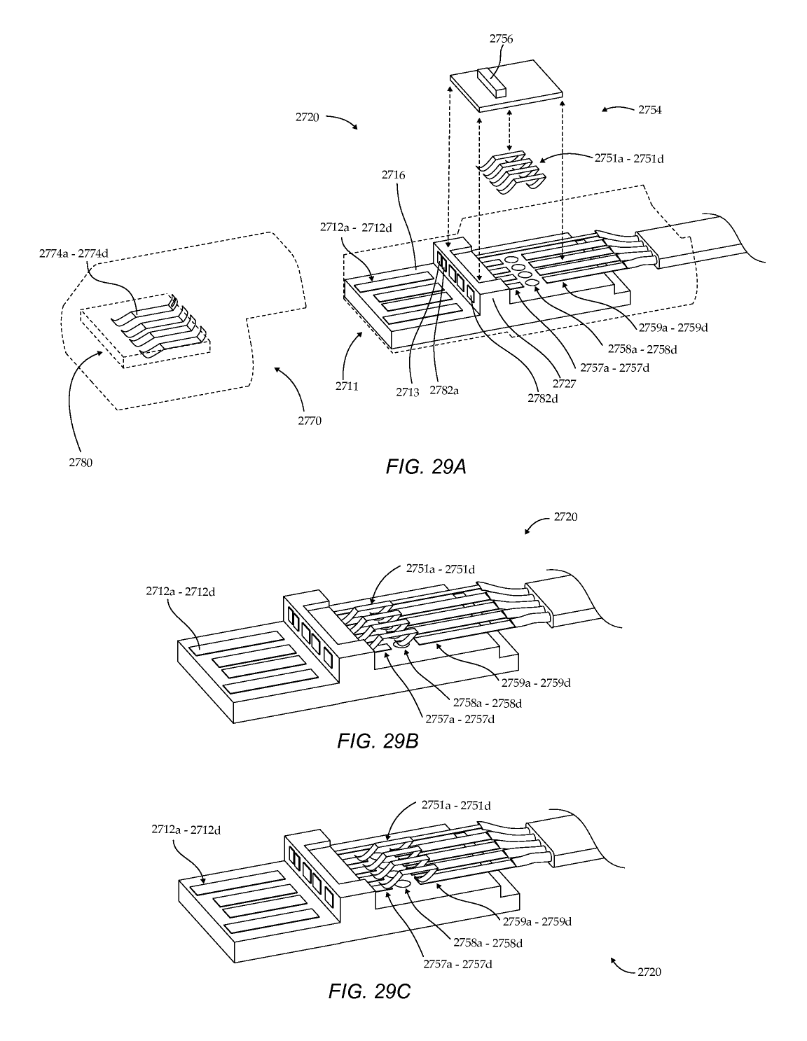

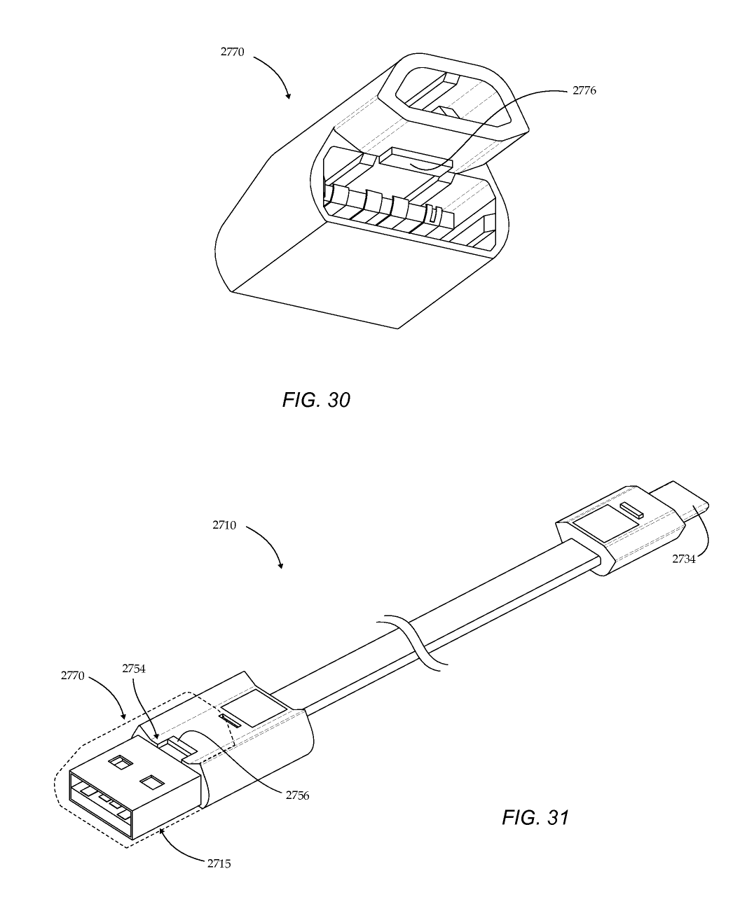

FIG. 29A is a partially exploded, transparent simplified perspective view of main body 2720 and switch structure 2780 of cap 2770 according to said embodiment. A function switch 2754 includes switch top 2756, a first plurality of contacts 2751a-2751d, a second plurality of contacts 2757a-2757d, a third plurality of contacts 2758a-2758d and a fourth plurality of contacts 2759a-2759d. First plurality of contacts 2751a-2751d is attached to switch top 2756, such that it can move back and forth together with switch top 2756 in a direction parallel to the length of main body 2720. Each of the second plurality of contacts 2757a-2757d is coupled, respectively, with a plurality of contacts 2712a-2712d on tongue 2711; third plurality of contacts 2758a-2758d is coupled with data storage component 2714 (shown in FIG. 28A); fourth plurality of contacts 2759a-2759d is coupled with second connector head 2734 (shown in FIG. 28A).

FIGS. 28B-28C are schematic representations of function switch 2754 in USB cable mode and in regular flash drive mode, respectively, according to said embodiment. FIGS. 29B-29C are partially transparent simplified perspective views in USB cable mode, regular flash drive mode, respectively, of main body 2720 according to said embodiment. When switch top 2756 (shown in FIG. 29A) of the function switch 2754 (functions switch 2754's schematic representation is shown in FIG. 28C) slides forward for regular flash drive mode, as shown in FIG. 29B, first plurality of contacts 2751a-2751d will be in contact with second plurality of contacts 2757a-2757d and third plurality of contacts 2758a-2758d, such that each of second plurality of contacts 2757a-2757d will be electrically coupled, respectively, with a contact from third plurality of contacts 2758a-2758d to connect a plurality of contacts 2712a-2712d of tongue 2711 with data storage component 2714 (shown in FIG. 28A). When switch top (shown in FIG. 29A) 2756 of function switch 2754 (functions switch 2754's schematic representation is shown in FIG. 28B) slides backward for USB cable mode, as shown in FIG. 29C, first plurality of contacts 2751a-2751d will be in contact with second plurality of contacts 2757a-2757d and forth plurality of contacts 2759a-2759d, such that each of second plurality of contacts 2757a-2757d will be coupled, respectively, with a contact from fourth plurality of contacts 2759a-2759d to further couple contacts 2712a-2712d on tongue 2711 with second connector head 2734 (shown in FIG. 28A).

As shown in FIG. 29A, OTG ID contact 2713 and a first plurality of contacts 2782a-2782d are on a supporting structure 2727 that extends longitudinally away from tongue 2711 in a direction perpendicular to surface 2716 of tongue 2711. As shown in FIG. 28A, OTG ID contact 2713 is coupled with second connector head 2734; contacts 2782a-2782d is coupled with data storage component 2714. As shown in FIG. 29A, a tongue 2780 of cap 2770 includes a plurality of contacts 2774a-2774d. When first connector head 2715 (shown in FIG. 27) is inserted into cap 2770, as shown in FIG. 28A, contact 2774a is coupled with contact 2712a (GND pin), OTG ID contact 2713 and contact 2782a (GND pin); contact 2774b is coupled with contact 2712b and contact 2782b; contact 2774c is coupled with contact 2712c and contact 2782c; contact 2774d is coupled with contact 2712d and contact 2782d. Meanwhile, if function switch 2754 is also in USB cable mode position (shown in FIG. 28B) to connect a plurality of contact 2712a-2712d to second connector head 2734, the combined result of cap 2770 and function switch 2754 turns the data storage/transfer device 2710 into an OTG flash drive to allow an OTG supported outside device, e.g., a mobile phone, to correspond to data storage component 2714 via second connector head 2734.

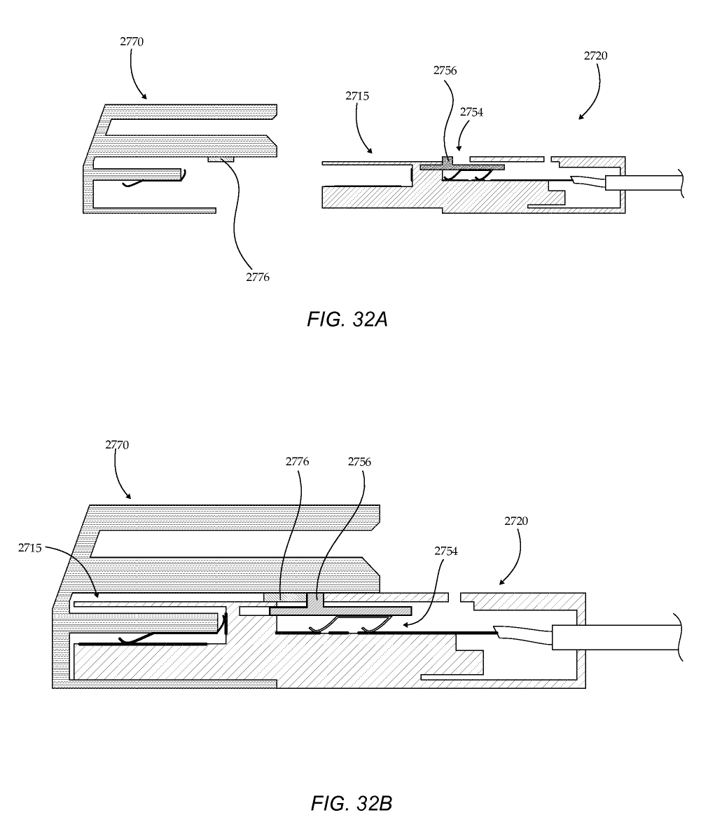

FIG. 31 is a simplified partially transparent perspective view of a data storage/transfer device 2710 in OTG flash drive mode, according to said embodiment. As shown in FIG. 31, in order to turn said embodiment into an OTG flash drive every time cap 2770 is put on, a mechanism is introduced, to spontaneously push switch top 2756 of function switch 2754 into USB cable mode position (shown in FIG. 28B). One of the methods, as shown in FIG. 30, is to use a block 2776 that is close to the edge of the lower cavity of cap 2770. FIGS. 32A-32B show how said mechanism works when switch top 2756 of function switch 2754 is initially in the forward position (regular flash drive mode position). When first connector head 2715 of main body 2720 is inserted into cap 2770, block 2776 of cap 2770 will push against switch top 2756 of function switch 2754 to move it backward into USB cable mode position, such that function switch 2754 changes from regular flash drive mode to USB cable mode position.

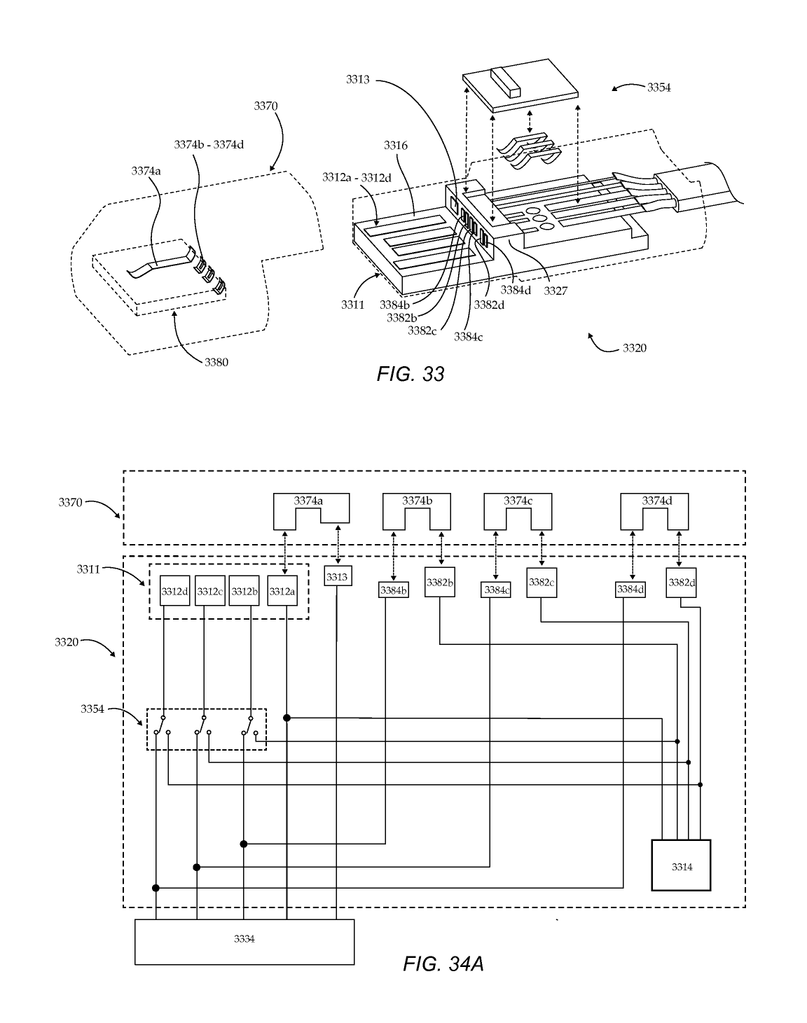

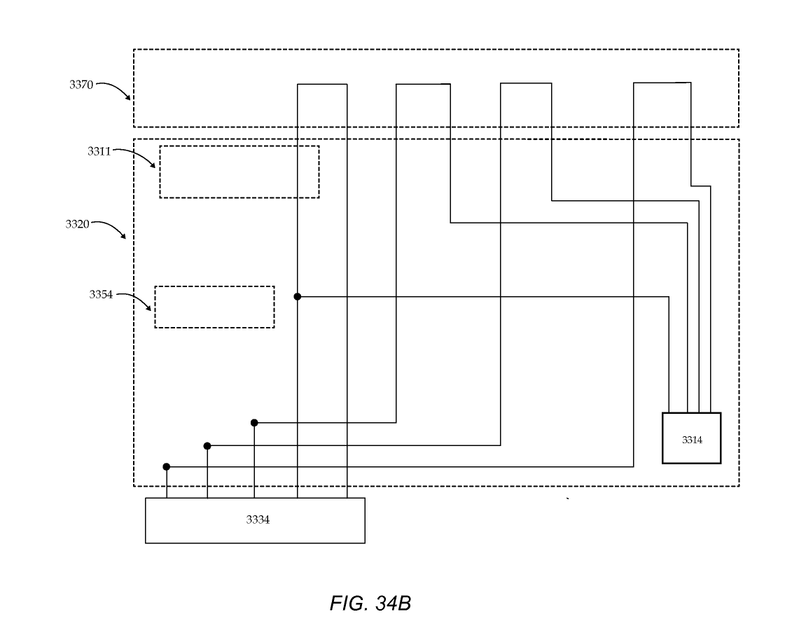

FIG. 33 is a simplified partially exploded, transparent perspective view, of a main body 3320 and a cap 3370 according to one embodiment of the present invention. FIG. 34A is a schematic representation of the connections between contacts 3374a-3374d, contacts 3312a-3312d, contacts 3382b-3382d, contacts 3384b-3384d, an OTG ID contact 3313, a function switch 3354, a data storage component 3314 and a second connector head 3334 according to said embodiment. Data storage component 3314 may be a memory card reader or an integrated memory chip to allow users to access and/or storage data. Data storage component 3314 includes contacts for Vcc (power), GND (ground) and a pair of differential data signals (D+, D−). Second connector head 3334 includes contacts for Vcc (power), GND (ground) and a pair of differential data signals (D+, D−). In some embodiments, second connector head 3334 may include additional contacts for special modes, such as OTG host mode. In FIG. 34A, function switch 3354 is simplified. This embodiment is similar to embodiments described above, e.g., data storage/transfer device 2710 in FIG. 27. However, as shown in FIG. 34A, contact 3312a is grounded and is permanently coupled with the GND pins of data storage component 3314 and second connector head 3334, such that compared to the embodiment in FIG. 29A, the complexity and total number of contacts of function switch 3354 are reduced. In FIG. 33, OTG ID contact 3313, a first plurality of contacts 3382b-3382d and a second plurality of contacts 3384b-3384d are on a support structure 3327 that extends longitudinally away from tongue 3311 in a direction perpendicular to surface 3316 of tongue 3311. As shown in FIG. 34A, first plurality of contacts 3382b-3382d is coupled with data storage component 3314, and second plurality of contacts 3384b-3384d is coupled with second connector head 3334.

In FIG. 33, a tongue 3380 of cap 2770 includes a plurality of contacts 3374a-3374d. When tongue 3311 of main body 3320 is inserted into cap 3370, then as shown in FIG. 34A, contact 3374a is in contact with contact 3312a, OTG ID contact 3313; contact 3374b is in contact with contact 3382b and contact 3384b; contact 3374c is in contact with contact 3382c and contact 3384c; contact 3374d is in contact with contact 3382d and contact 3384d. FIG. 34B is a simplified schematic representation of the connection between data storage component 3314 and second connector head 3334 when tongue 3311 of main body 3320 is inserted into cap 3370 to activate OTG flash drive mode. Therefore, an OTG supported outside device, such as a mobile phone, that connects with this data storage/transfer device via second connector head 3334 may turn on OTG function and correspond to data storage component 3314, regardless the status of function switch 3354. The advantage over the embodiment shown in FIG. 27, FIGS. 28A-28C, FIGS. 29A-29C, FIG. 30, FIG. 31 and FIGS. 32A-32B is that this method doesn't reset the position of function switch 3354 to USB cable mode following putting on the cap.

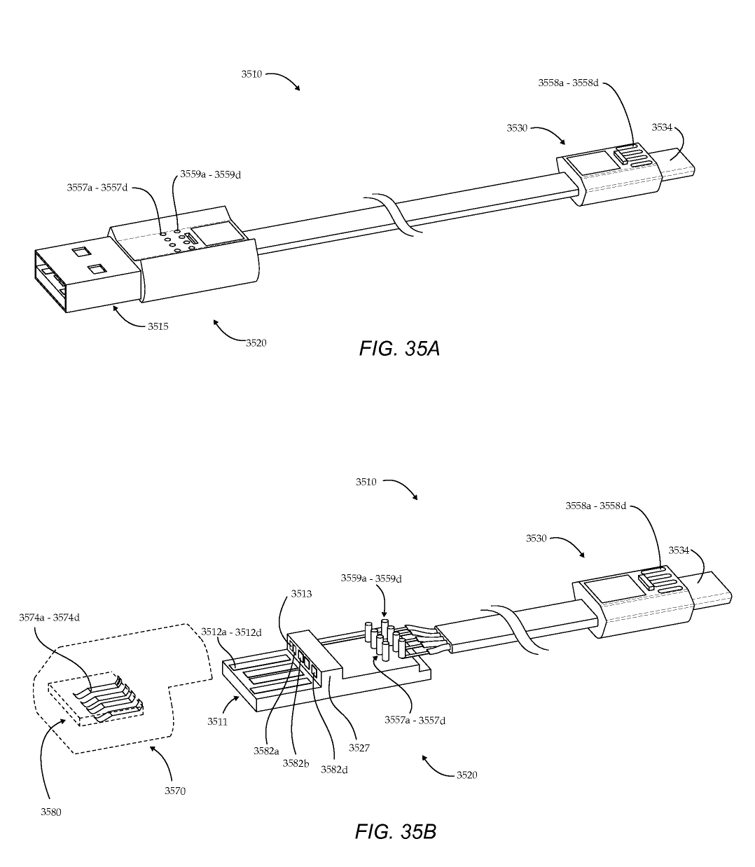

FIG. 35A is a simplified perspective view of a data storage/transfer device 3510 without a cap 3570 shown in FIG. 35B, according to one embodiment of the present invention. This embodiment is similar to the embodiments described above, e.g., the embodiment shown in FIG. 27, FIGS. 28A-28C, FIGS. 29A-29C, FIG. 30, FIG. 31 and FIGS. 32A-32B. However, a second connector 3530 has a third plurality of contacts 3558a-3558d that may be used to connect a first plurality of contacts 3557a-3557d and a second plurality of contacts 3559a-3559d that are exposed on main body 3520. FIG. 35B is a partially transparent simplified perspective view of the data storage/transfer device 3510. An OTG ID contact 3513 and a plurality of contacts 3582a-2582d is on a supporting structure 3527; cap 3570 is similar or identical to the cap 2770 in FIG. 29A.

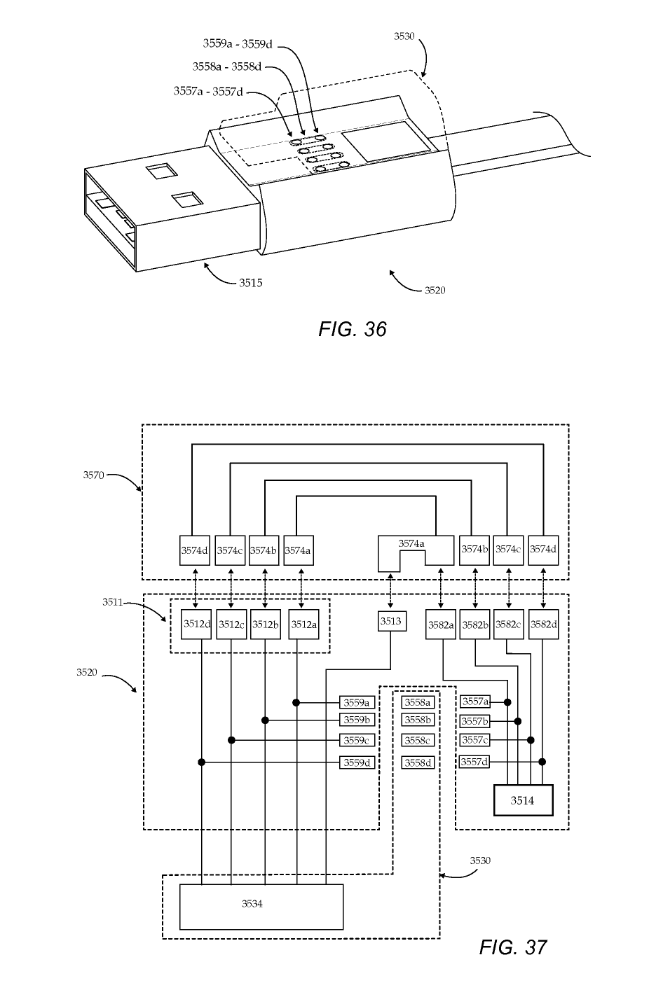

FIG. 36 is a partially transparent simplified perspective view of a second connector 3530 attaching to a main body 3520. FIG. 37 is a schematic representation of the connections between contacts 3574a-3574d, contacts 3512a-3512d, contacts 3582a-3582d, an OTG ID contact 3513, contacts 3557a-3557d, contacts 3558a-3558d, contacts 3559a-3559d, a data storage component 3514 and a second connector head 3534 of second connector 3530, according to said embodiment. Data storage component 3514 may be a memory card reader or an integrated memory chip to allow users to access and/or storage data. Data storage component 3514 includes contacts for Vcc (power), GND (ground) and a pair of differential data signals (D+, D−). Second connector head 3534 includes contacts for Vcc (power), GND (ground) and a pair of differential data signals (D+, D−). In some embodiments, second connector head 3534 may include additional contacts for special modes, such as OTG host mode. In FIG. 37, contacts 3512a-3512d and contacts 3559a-3559d are coupled with second connector head 3534 of second connector 3530; contacts 3582a-2582d and contacts 3557a-3557d are coupled with data storage component 3514 of main body 3520; contacts 3558a-3558d are on the housing of second connector 3530 but not electrically coupled with any other contacts, unless in the state shown in FIG. 36. When main body 3520 and second connector 3530 are not attached to each other or to a cap, the embodiment of the present invention works as a USB cable.

In FIG. 36, when second connector 3530 (shown in dash lines) folds back and releasably attaches to main body 3520, each of third plurality of contacts 3558a-3558d (shown in dash lines) will be in touch with a contact from first plurality of contacts 3557a-3557d and a contact from second plurality of contacts 3559a-3559d. Contact 3557a will connect contact 3559a via contact 3558a; Contact 3557b will connect contact 3559b via contact 3558b; contact 3557c will connect contact 3559c via contact 3558c; contact 3557d will connect contact 3559d via contact 3558d. In this way, as shown in FIG. 37, contacts 3512a-3512d will be coupled with data storage component 3514. In this situation described above, as shown in FIG. 36, second connector 3430 is attached to main body 3520 and physically limits the space around itself, therefore second connector 3430 is then unlikely to be inserted into an outside device. Consequently, the embodiment of the present invention may work as a regular flash drive exclusively via the first connector head 3515 (shown in FIG. 35A). When second connector 3530 is unattached from main body 3520, and second plurality of contacts 3559a-3559d doesn't couple with first plurality of contacts 3557a-3557d, accordingly the embodiment of the present invention functions as an USB cable. To use as an USB cable, the embodiment is usually in a stretched state similar to the state shown in FIG. 35A. The advantage is that, in most situations, the appearance of USB cable mode is sufficiently different from the regular flash drive mode. Therefore, it is more intuitive to tell which mode the device is in, than using a function switch described in FIG. 29A.

As shown in FIG. 35B and FIG. 37, when first connector head 3515 (shown in FIG. 35A) of main body 3520 is inserted into cap 3570 to activate OTG flash drive mode, second connector 3530 need to be detached from main body 3520. Contact 3512a is a GND pin. Therefore, contact 3559a-3559d will be disconnected from contacts 3557a-3557d; contact 3574a will connect to OTG ID contact 3513, grounded contact 3512a and contact 3582a; contact 3574b will connect to contact 3512b and contact 3582b; contact 3574c will connect to contact 3512c and contact 3582c; contact 3574d will connect to contact 3512d and contact 3582d. Consequently, second connector head 3534 will connect to data storage component 3514 and have its OTG ID pin grounded to activate OTG function. Therefore, this embodiment of the present invention functions as an OTG flash drive to allow an outside OTG supported device, e.g., a mobile phone, to correspond to data storage component 3514 via second connector head 3554 of second connector 3530. The advantage of using cap 3570 (shown in FIG. 35A) as OTG switch to turn on OTG flash drive mode and block first connector head 3515 (shown in FIG. 35B) of main body 3520 from plugging into a receptacle connector is that, an outside device may correspond exclusively to second connector head 3534, therefore, a user cannot connect an outside device to a wrong connector and confuse the device (foolproof purpose).

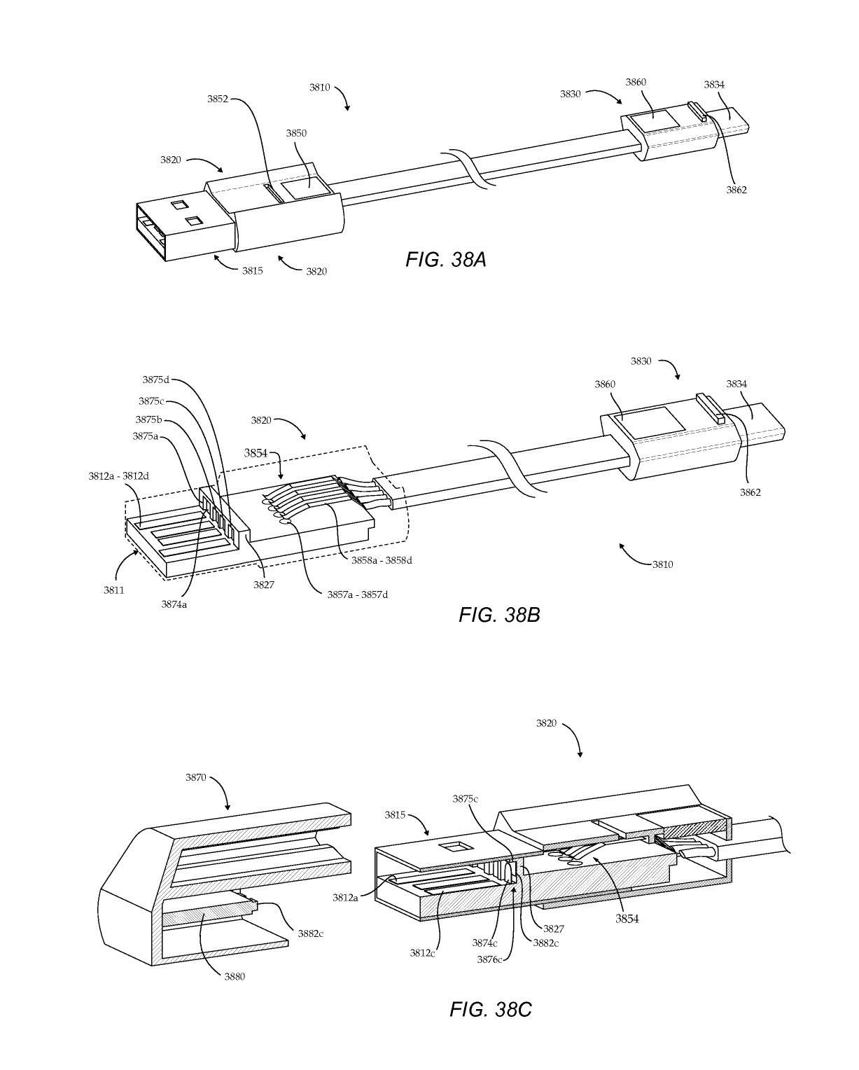

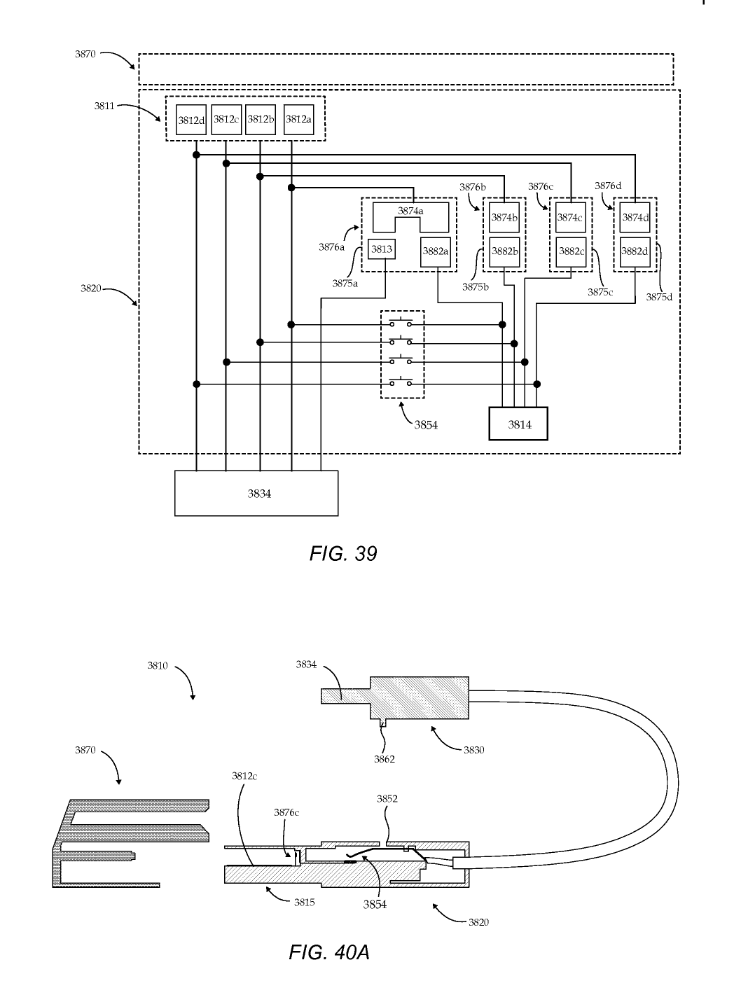

FIGS. 38A-38B are a simplified perspective view and a partially transparent simplified perspective view, respectively, of a data storage/transfer device 3810 without a cap 3970 shown in FIG. 38C, according to one embodiment of the present invention. FIG. 38C is a simplified perspective and cross sectional view, of a main body 3820 and cap 3870, according to said embodiment. FIG. 39 is a schematic representation of the connections between contacts 3812a-3812d, contacts 3874a-3874d, contacts 3882a-3882d, an OTG ID contact 3813, a push switch 3854, a data storage component 3814 and a second connector head 3834, according to said embodiment. Data storage component 3814 may be a memory card reader or an integrated memory chip to allow users to access and/or storage data. Data storage component 3814 includes contacts for Vcc (power), GND (ground) and a pair of differential data signals (D+, D−). Second connector head 3834 includes contacts for Vcc (power), GND (ground) and a pair of differential data signals (D+, D−). In some embodiments, second connector head 3834 may include additional contacts for special modes, such as OTG host mode. In FIG. 39, push switch 3854 is a simplified multi-pole, single throw function switch. This embodiment is similar to the embodiments described above, e.g., the embodiment shown in FIGS. 35A-35B, FIG. 36 and FIG. 37. However, as shown in FIG. 38B, this embodiment has a push switch 3854 that determines whether the data storage/transfer device 3810 is in regular flash drive mode or USB cable mode, when the first connector head 3815 (shown in FIG. 38C) of main body 3820 is not inserted into a cap 3870 (shown in FIG. 38C). Push switch 3854 includes a first plurality of contacts 3857a-3857d, which is coupled with data storage component 3814 (shown in FIG. 39), and a second plurality of spring contacts 3858a-3858d, which is coupled with second connector head 3834 (shown in FIG. 39). Push switch 3854 stays in OFF position when no external force is applied. A plurality of cavities 3875a-3875d is on support structure 3827, and each cavity of plurality of cavities 3875a-3875d includes, respectively, one of the push switches 3876a-3876d (shown in FIG. 39). For example, as shown in 38C, contact 3882c is on the rear wall of cavity 3875c, and a spring contact 3874c stands in the space defined by cavity 3875c such that it is close to, but not touching contact 3882c when no external force is applied. Contact 3882c and spring contact 3874c form a push switch 3876c, which stay in OFF position when no external force is applied. As shown in FIG. 39, push switches 3876b, 3876d, respectively, in cavity 2875b, 2875d are similar or identical to the embodiment in cavity 3875c described above. In FIG. 38C, tongue 3880 of cap 3870 includes a plurality of nubs 3882a-3882d (only contact 3882c is shown). Each of the plurality of nubs 3882a-3882d is sufficiently smaller than each of corresponding cavities 3875a-3875d on support structure 3827.

As shown in FIG. 39, spring contacts 3874a-3874d are coupled, respectively, with contacts 3812a-3812d of tongue 3811 of first connector head 315; OTG ID contact 3813 is coupled with OTG ID pin of second connector head 3834; contacts 3883a-3883d are coupled with data storage component 3814. Push switch 3876a in cavity 3875a includes spring contact 3874a, which is grounded, may connect with OTG ID contact 3813 and contact 2882a when external force is applied. If push switches 3876a-3876d and push switch 3854 are in OFF position, this embodiment is in USB cable mode via first connector head 3815 (shown in FIG. 38A) and second connector head 3834; if push switches 3876a-3876d are in OFF position, and push switch 3854 is in ON position, this embodiment is in regular flash drive mode; if push switches 3876a-3876d and push switch 3854 are in ON position, this embodiment is in OTG flash drive mode;

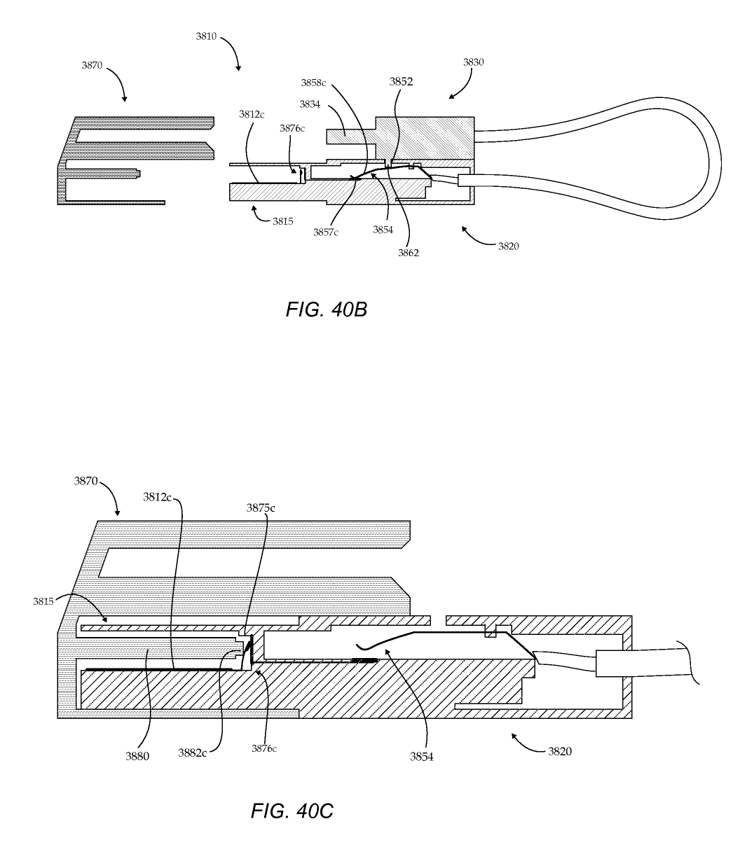

FIGS. 40A-40B are simplified cross sectional views of a data storage/transfer device 3810 in USB cable mode and regular flash drive mode, respectively, according to said embodiment. FIG. 40C is a simplified cross sectional view of main body 3820 and cap 3870 with first connector head 3815 of main body 3820 inserted into cap 3870 to enable OTG flash drive mode, according to said embodiment. In FIG. 40A, push switches 3876a-3876d and push switch 3854 (only push switches 3876c and 3854 are shown) are in OFF position; contacts 3812a-3812d are coupled with second connector head 3834 (only contact 3812c is shown) and not coupled with data storage component. Therefore, data storage/transfer device 3810 is in USB cable mode. In FIG. 40B, second connector 3830 is attached to main body 3820. Unlike in FIG. 40A, which a nub 3862 of second connector 3830 is not inserted into an opening 3852 such that push switch 3854 stays in OFF position, nub 3862 of second connector 3830 in FIG. 40B is inserted into opening 3852 and pushing spring contacts 3858a-3858d (only spring contact 3858c is shown) in touch with contacts 3857c (only contact 3857c is shown) such that push switch 3854 is in ON position. Meanwhile, push switches 3876a-3876d (only push switch 3876c is shown) stays in OFF position. Data storage/transfer device 3810 then functions as regular flash drive via contacts 3812a-3812d of first connector head 3815 of main body 3820. The advantage is that, in most situations, the appearance of USB cable mode is sufficiently different from the regular flash drive mode. Therefore, it is more intuitive to tell which mode the device is in.

FIG. 40C is a simplified cross sectional view of main body 3820 and cap 3870 with first connector head 3815 of main body 3820 inserted into cap 3870 to enable OTG flash drive mode. First connector head 3815 of main body 3820 is inserted into cap 3870 and second connector 3830 (doesn't shown) is not attached to main body 3820. The plurality of nubs 3882a-3882d (only nubs 3882c is shown) of tongue 3880 of cap 3870 is inserted, respectively, into cavity 3875a-3875d (only cavity 3875c is shown), such that push switches 3876a-3876d (only push switches 3876c is shown) are pushed into ON position. Push switch 3854 stays in OFF position. Therefore, this embodiment of the present invention is in OTG flash drive mode. The advantage of using cap 3870 as OTG switch to turn on OTG flash drive mode and block first connector head 3815 (shown in FIG. 40C) of main body 3820 from plugging into a receptacle connector is that, an outside device may correspond exclusively to second connector head 3834 (shown in FIG. 39, therefore, a user cannot connect an outside device to a wrong connector and confuse the device (foolproof purpose).

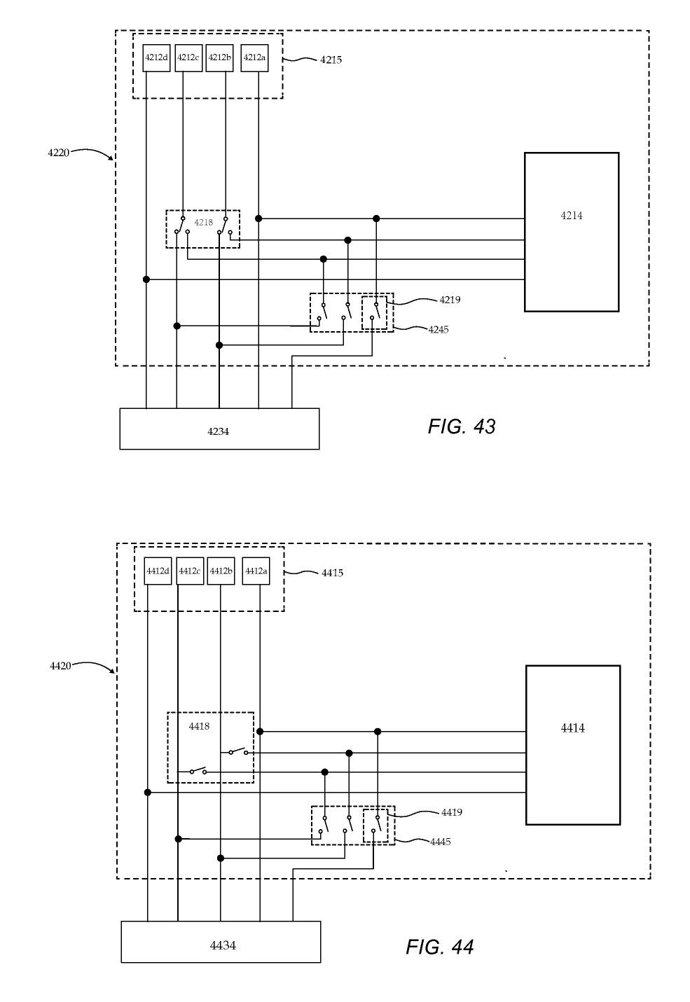

FIG. 42 is a simplified perspective view of a data storage/transfer device 4210 according to one embodiment of the present invention. FIG. 43 is a schematic representation of the connections between GND contact 4212a, D+ contact 4212b, D− contact 4212c, Vcc contact 4212d, a switching circuit 4218, a switching circuit 4245, a data storage component 4214 and a second connector head 4234, according to one particular embodiment of the present invention shown in FIG. 42. This embodiment is similar to the embodiments described above, e.g., the embodiment shown in FIGS. 38A-38C, FIG. 39, FIG. 40A-40C. Data storage component 4214 may be a memory card reader or an integrated memory chip to allow users to access and/or storage data. Data storage component 4214 includes contacts for Vcc (power), GND (ground) and a pair of differential data signals (D+, D−). Second connector head 4234 includes contacts for Vcc (power), GND (ground) and a pair of differential data signals (D+, D−). In some embodiments, second connector head 4234 may include additional contacts for special modes, such as OTG host mode.

However, switching circuit 4218, switching circuit 4245, as shown in FIG. 43, are used to, respectively, provide functions similar to push switch 3854, push switches 3876a-3876d (shown in FIG. 39 and FIG. 40A-40C). In FIG. 43, contact 4212a is for GND (ground); contact 4212b is for D+, contact 4212c is for D−, contact 4212d is for Vcc (power). D+ and D− are a pair of USB differential data. Contact 4212a for GND and contact 4212d for Vcc are coupled with second connector head 4234 and data storage component 4214 to reduce overall circuit complexity. Contact 4212b for D+ and contact 4212c for D− are coupled, respectively to switching circuit 4218 and switching circuit 4245. Switching circuit 4218 comprise a DPDT (double pole, double throw) analogue switch to selectively couple contacts 4212b-4212c with second connector head 4234 or data storage component 4214. Switching circuit 4218 is triggered by a magnetic-sensitive component 4280 (shown in FIG. 42) that can be triggered by predetermined magnetic conditions. As shown in FIG. 42, data storage/transfer device 4210 comprises magnets 2450 and magnet 4260, such that second connector 4230 can be attracted and releasably attached to main body 4220 when the embodiment of the present invention is a folded state similar to the embodiment in FIG. 8B. The position of magnet 4250 in relation to magnetic-sensitive component 4280 is predetermined, therefore the magnetic field around magnetic-sensitive component 4280 generated by magnet 4250 is predetermined; the position of magnet 4260 in relation to magnetic-sensitive component 4280 varies according to the position of second connector 4230, therefore the magnetic field around magnetic-sensitive component 4280 generated by magnet 4260 varies accordingly. Assuming there is no other outside magnet near data storage/transfer device 4210, when second connector 4230 is attached to main body 4220 similar to the embodiment in FIG. 8B, the overall intensity of magnetic field around magnetic-sensitive component 4280 generated by magnet 4250 and magnet 4260 is high enough to trigger magnetic-sensitive component 4280 to further trigger switching circuit 4218 (shown in FIG. 43) to couple contacts 4212b-4212c (shown in FIG. 43) of first connector head 4215 with data storage component 4214. This embodiment is then in regular flash drive mode. When second connector 4230 is separated from main body 4220 over a sufficient distance, such that magnet 4260 is away from magnetic-sensitive component 4280 over a sufficient distance, the overall intensity of magnetic field on magnetic-sensitive component 4280, created by magnet 4250 and magnet 4260, is low enough to trigger magnetic-sensitive component 4280 to further trigger switching circuit 4218 (shown in FIG. 43) to couple contacts 4212b-4212c (shown in FIG. 43) of first connector head 4215 with second connector head 4234. This embodiment is then in USB cable mode. To increase switching reliability, additional magnets may be applied on data storage/transfer device 4210 to adjust magnetic condition around magnetic-sensitive component 4280. In other embodiments, second connector may be attached to main body by non-magnetic means, such as embodiments shown in FIGS. 5A-5B, FIGS. 6A-6B, then a single magnet may be used on second connector thereof to trigger a magnetic-sensitive component. Switching circuit 4245 comprises a analogue DPST (double pole, single throw) switch to selectively couple data signal pins (D+, D−) of second connector head 4234 to data storage component 4214, and an OTG ID switch 4219 for turning on OTG host mode on second connector 4234. The states of the DPST analogue switch ara governed by the states of OTG ID switch 4219. When OTG ID switch 4219 is turned off, it will trigger the DPST analogue switch to turn off. When OTG ID switch 4219 is turned on for OTG host mode, it will also turn on the DPST analogue switch to couple data signal pins (D+, D−) of second connector head 4234 with data storage component 4214. Consequently, the embodiment of the present invention then can function as an OTG flash drive by plugging second connector head 4234 into an OTG supported external device. In some embodiments, OTG ID switch 4219 is a switching mechanism triggered by putting a cap 4270 (shown in FIG. 42) on first connector head 4215 (shown in FIG. 42). For examples, in some embodiments, the mechanical structure of OTG ID switch 4219 is identical or similar to push switches 3876c (shown in FIG. 38C, FIG. 39); in some other embodiments, the mechanical structure of OTG ID switch 4219 is identical or similar to the mechanical structure of contact 3374a, contact 3312a and contact 3313 (shown in FIG. 33, FIG. 34). Consequently, when the embodiment functions as an OTG flash drive, first connector head 4215 is blocked by cap 4270 (shown in FIG. 42), and second connector head 4234 is exposed, to indicate the correct connector head (foolproof purpose) to a user for using as OTG flash drive.

FIG. 44 is a schematic representation of the connections between contact 4412a-4412d, a switching circuit 4418, a switching circuit 4445, data storage component 4414 and a second connector head 4434, according to one embodiment of the present invention. Data storage component 4414 may be a memory card reader or an integrated memory chip to allow users to access and/or storage data. Data storage component 4414 includes contacts for Vcc (power), GND (ground) and a pair of differential data signals (D+, D−). Second connector head 4434 includes contacts for Vcc (power), GND (ground) and a pair of differential data signals (D+, D−). In some embodiments, second connector head 4434 may include additional contacts for special modes, such as OTG host mode. This embodiment is similar to the embodiments described above, e.g., the embodiment shown in FIG. 43. However, contacts 4412b-4412c for data signal (D+. D−) are permanently coupled with second connector head 4434, and switching circuit 4418 comprise a DPST (double pole, single throw) analogue switch to selectively couple contacts 4212b-4212c with data storage component 4414. Switching circuit 4445 with an OTG ID switch 4445 is similar or identical to switching circuit 4245 shown in FIG. 43.

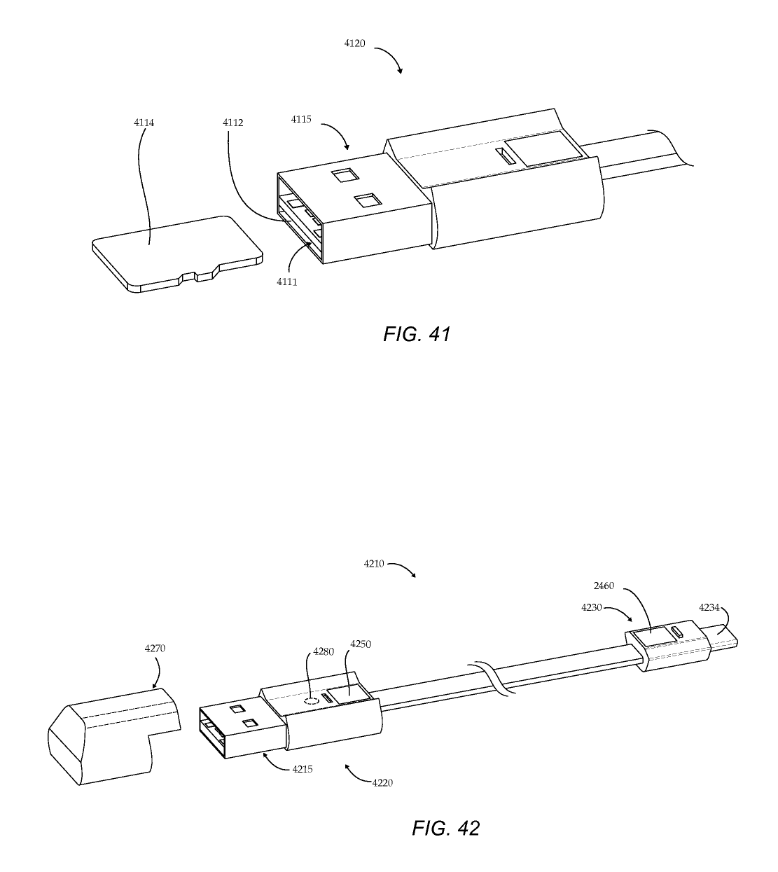

FIG. 41 is a simplified perspective view of a memory card 4114 and a main body 4120 of a data storage/transfer device according to one embodiment of the present invention. This embodiment of the present invention is similar to the embodiments described above. However, this embodiment uses a combination of a memory card reader and a removable memory card 4114 to replace an integrated memory chip. A memory card 4114 such as a Micro SD card, may be inserted into cavity 4112 under tongue 4111 of a first connector 4115 of main body 4120. The advantage over an integrated data storage component is that the embodiment may functions as a card reader and allow memory capacity upgrade by using a different memory card.

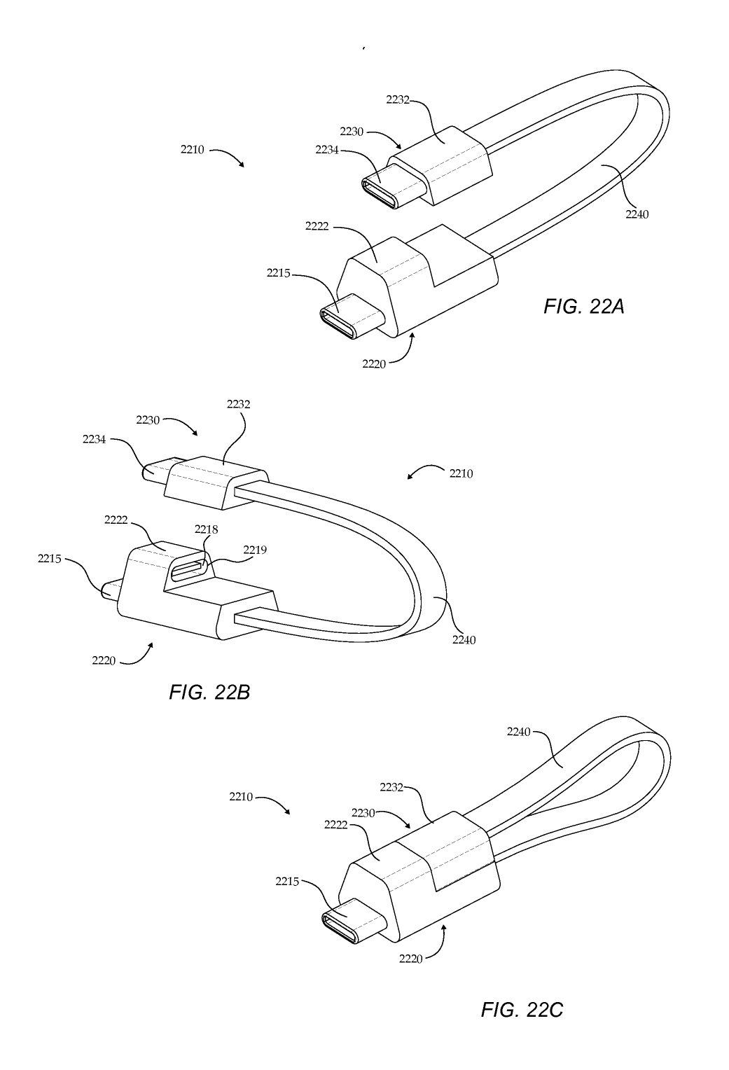

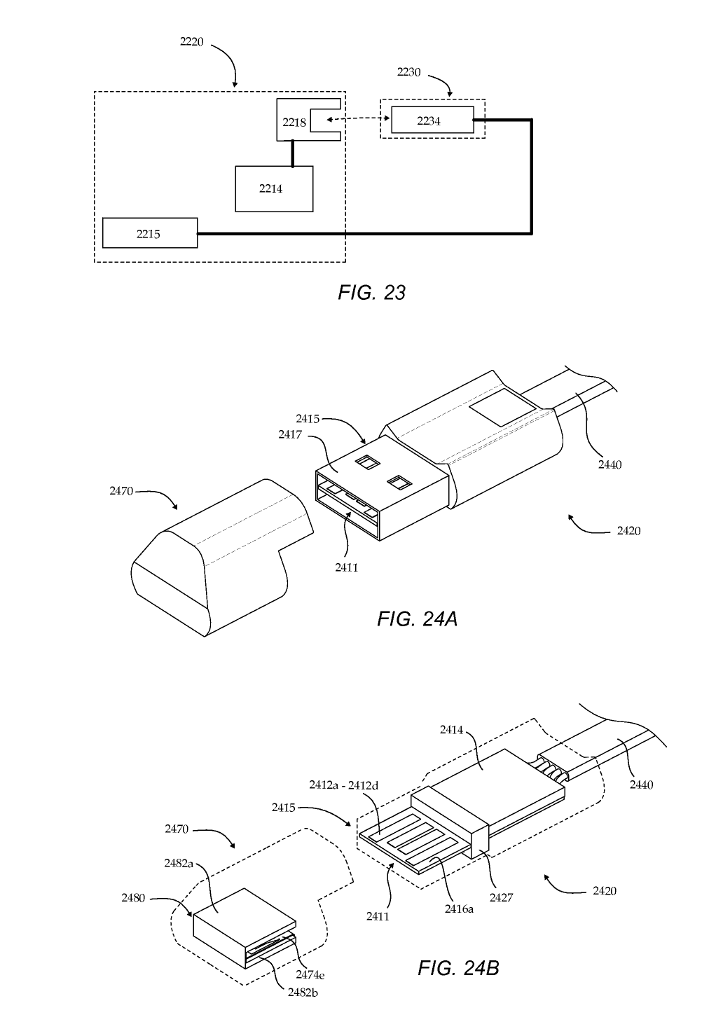

FIGS. 22A-22C are simplified perspective views of a data storage/transfer device 2210 according to one embodiment of the present invention. Data storage/transfer device 2210 includes a main body 2220, a cable 2240 and a second connector 2230. Main body 2220 includes a housing 2222, a first connector head 2215 such as a USB Type-C connector head, a receptacle connector port 2218 (shown in FIG. 22B) and a data storage component 2214 (shown in FIG. 23). Data storage component 2214 may be a memory card reader or an integrated memory chip to allow users to access and/or storage data. Data storage component 2214 includes contacts for power, GND ground and data signals. Second connector head 2234 includes contacts for power, ground and data signals. In some embodiments, second connector head 2234 may include additional contacts for special modes, such as OTG host mode. Receptacle connector port 2218 can be fit into the opening 2219 of housing 2222. Second connector 2230 includes a housing 2232 and a second connector head 2234 such as a USB Type-C connector head which can be inserted into the cavity defined by the inner surface of receptacle connector port 2218 of main body 2220. In some embodiments of the present invention, first and second connector head may be USB connector head types other than USB Type-C, such as USB Type-A or Micro-B USB.

The embodiments described above use technical standards mainly from USB 2.0 specification to illustrate the functions. However, in some other embodiments, the present invention may use other technical standard, such as technical standards from USB 3.0 specification, to achieve identical or similar data storage and transfer functions. Therefore, the total number and functions of the contacts may vary according to the specific technical standards using on specific embodiments, e.g., besides contacts for Vcc, GND, D+(for signal) and D− (for signal), a USB 3.0 Type-A connector head may also include contacts for StdA_SSTX+ (for signal), StdA_SSTX− (for signal). StdA_SSRX+ (for signal), StdA_SSRX− (for signal) and GND_DARIN.

FIG. 23 is a simplified schematic representation of the connections between first connector head 2215, second connector head 2234, receptacle connector port 2218 and data storage component 2214 according to one particular embodiment of the present invention shown in FIGS. 22A-22C. First connector head 2215 is electrically coupled with second connector head 2234. Data storage component 2214 is coupled with receptacle connector port 2218. This particular embodiment has a USB cable mode and a regular flash drive mode. When the second connector head is not inserted into receptacle connector port 2218, this embodiment of the present invention functions as a regular USB cable with connectors on two ends; when second connector head 2234 is inserted into and coupled with receptacle connector port 2218, first connector head 2215 is coupled with data storage component 2214, and this embodiment functions as a regular USB flash drive. The advantage is when the present invention functions as a USB cable, first connector head 2215 and second connector head 2234 are exposed to the user, and data storage component electrically disconnects from first connector head 2215 and second connector head 2234. When the embodiment functions as a regular USB flash drive, second connector head 2234 is inserted into receptacle connector port 2218 and coupled with data storage component 2214, first connector head 2215 then is the single fully exposed connector head that is used to communicate with outside devices such as personal computers. Each mode has distinctive appearance differences and non-interchangeable operation processes, therefore, may reduce the potential user frustration during operations under various situations.

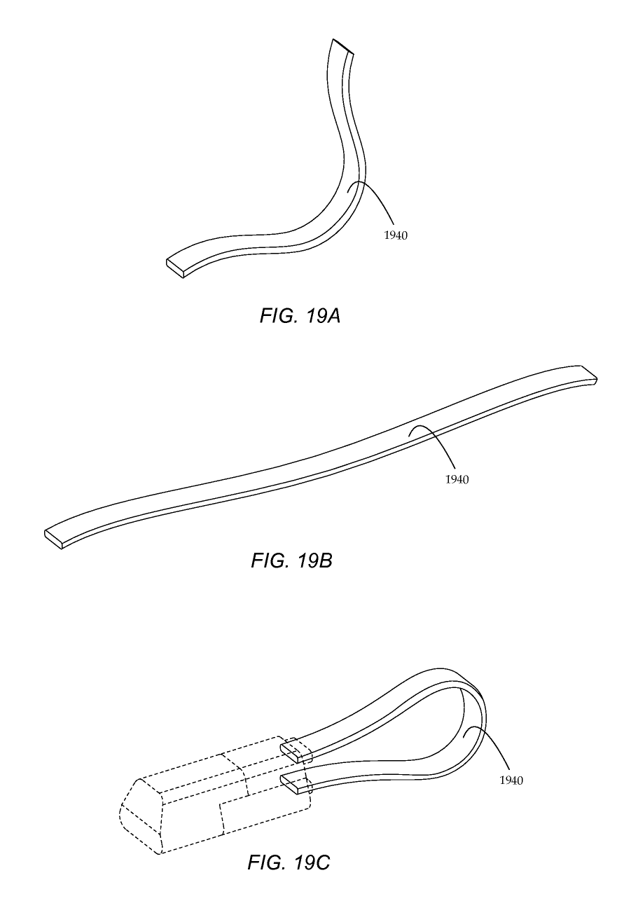

In some of embodiments of the present invention, the cable that connects a main body and a second connector may be molded into L-shape, e.g., cable 1940 in FIG. 19A. The advantage over a regular cable will be described below. A regular cable which has a naturally straight form may last a shorter time than cable 1940, due fatigue. A cable of embodiments of the present invention usually have an extended state shown in FIG. 19B and a folded state shown in FIG. 19C. A regular naturally straight cable may be good for the extended state, but will be bended approximately 180 degrees over for a folded state. In contrast, cable 1940 with natural L-shape shown in FIG. 19A will only need to be bended approximately 90 degrees to reach an extended state or a folded state, therefore may result in less internal stress than a regular cable and less damage from fatigue.

Cable 1940 may have a flat sectional profile, wherein cable 1940 may be wider but thinner comparing to a standard round-section cable with similar sectional area, such that cable 1940 can be folded in the way as shown in FIG. 19A-19C with less internal stress.

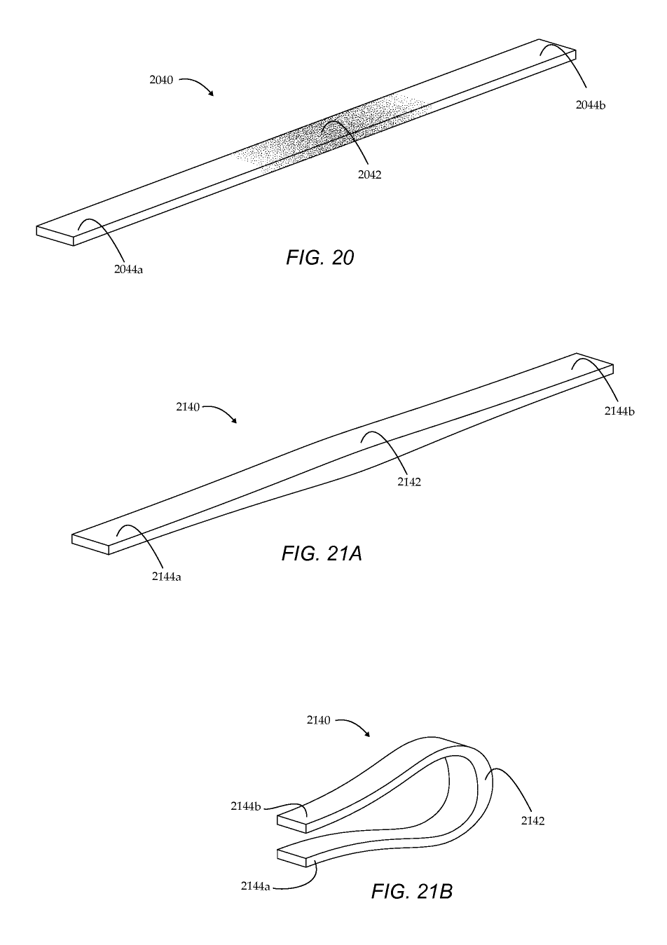

FIG. 20 is a simplified perspective view of a cable 2040 in natural form without external force, according to one embodiment of the present invention. The jacket of middle section 2042 of cable 2040 is made of material with greater hardness, such as silicone with a durometer of 70 Shore A, than the material for the jacket used for cable ends 2044a-2044b, such as silicone with only a durometer of 40 Shore A. The jacket material used in middle section 2042 of cable 2040 may be gradually mixed with the jacket material used in cable ends 2044a-2044b, such that the hardness of cable 2040 varies consistently in a direction paralleled to the length of cable 2040. When cable 2040 is bended into the shape similar to what is shown in FIG. 19C, comparing to a cable made of uniform hardness, the middle section of cable 2040 has less tendency to pinch under external force.

FIG. 21A is a simplified perspective view, of a cable 2140 in natural form without external force, according to one embodiment of the present invention. The jacket of cable 2140 may be made of the same or similar material with uniform durometer from a cable end 2144a, to middle section 2142, and to a cable end 2144b. The thickness of cable 2140 in middle section 2142 is substantially greater than cable ends 2144a-2144b. The thickness of cable 2140 may be at the greatest in middle section 2142 and gradually decrease along either direction toward cable end 2144a or cable end 2144b. When the cable is made of the same or similar material with uniform durometer, the thicker the cable is, then the higher the resistance will be when the cable deforms. When cable 2140 is bended into the shape as shown in FIG. 21B, middle section 2142 of cable 2140 generates stronger resistance against bending force than cable ends 2144a-2144b, due to the thickness differences.

In some of embodiments of the present invention, the cable of the present invention may be applied with more than one method shown in FIGS. 19A-19C, FIG. 20 and FIG. 21A-21B.

For an example, in some embodiments, the cable of the present invention may have a natural form similar to cable 1940 in FIG. 19A, and be made of materials with different hardness, as shown in FIG. 20, and has thickness that varies in a direction parallel to the length of the cable similar to cable 2140 in FIGS. 21A-21B.

I claim:

1. A data storage and transfer device comprising:
a. a main body including at least a first connector head, wherein said first connector head includes a first plurality of data contacts;
b. at least a second connector including a second connector head, wherein said second connector head includes a second plurality of data contacts;
c. at least a cable connecting said main body and said second connector, wherein said second connector can be releasably attached to said main body by folding said cable;
d. data storage means for storing data; and
wherein said first plurality of data contacts is electrically coupled with said data storage means when said second connector is close to said main body within a predetermined distance, and said first plurality of data contacts is electrically coupled with said second plurality of data contacts when said second connector is separated from said main body over another predetermined distance.

2. Said main body set forth in claim 1 further comprising a second receptacle connector port permanently coupled with said data storage means, wherein said cable is permanently, electrically coupled with said first plurality of data contacts and said second plurality of data contacts, and said second plurality of data contacts can be electrically coupled with said data storage means by folding said cable and mating said second connector head with said second receptacle connector port.

3. Said data storage and transfer device set forth in claim 1 further comprising a first switching circuit wherein said first switching circuit can selectively, electrically couple said first plurality of data contacts with said second plurality of data contacts or said data storage means.

4. Said switching circuit set forth in claim 3 further comprising mechanical means wherein said mechanical means are used to determine the proximity of said second connector to said main body.

5. Said data storage and transfer device set forth in claim 3 further comprising magnetic-sensitive means and at least one magnet, wherein said magnet is carried by said second connector, and said magnetic-sensitive means is used to determine the proximity of said second connector to said main body.

6. Said data storage and transfer device set forth in claim 1 further comprising a cap to mate with said first connector head to enable a special mode and electrically couple said second plurality of data contacts with said data storage means.

7. Said cap set forth in claim 6 further comprising means to trigger a special mode.

8. Said special mode set forth in claim 7 wherein said special mode is USB OTG mode.

9. Said first connector head set forth in claim 1 wherein said first connector head is an USB connector head.

10. Said second connector head set forth in claim 1 wherein said second connector head is a Micro USB connector head.

11. Said data storage means set forth in claim 1 wherein said data storage means is a memory.

12. Said data storage means set forth in claim 1 wherein said data storage means is a memory card reader

13. A data storage and transfer device comprising:
a. a main body including at least a first connector head;
b. a first plurality of contacts carried by said first connector head at a first surface;
c. a second plurality of contacts carried by said first connector head at a second surface;
d. at least a second connector including a second connector head;
e. data storage means for storing data; and
wherein said first plurality of contacts is electrically coupled with said data storage means, and said second plurality of contacts is electrically coupled with said second connector head.

14. Said data storage and transfer device set forth in claim 13 further comprising a cap to mate with said first connector head to electrically couple said first plurality of contacts with second plurality of contacts.

15. Said cap set forth in claim 14 further comprising means to trigger a special mode.

16. Said data storage means set forth in claim 13 wherein said data storage means is a memory.

17. Said data storage mean set forth in claim 13 wherein said data storage means is a memory card reader.

18. A data storage and transfer device comprising:
a. a main body including at least a first connector head;
b. at least a second connector including a second connector head;
c. data storage means for storing data;
d. an hub controller; and
wherein said hub controller is electrically coupled with said first connector head, said second connector head and said data storage means.

19. Said data storage means set forth in claim 18 wherein said data storage means is a memory.

20. Said data storage means set forth in claim 18 wherein said data storage means is a memory card reader
